(19) United States
(12) Patent Application Publication
(10) Pub. No.: US 2026/0324246 A1
(43) Pub. Date: Oct. 15, 2026

(54) ELECTRONIC DEVICE

(71) Applicant: Samsung Display Co., Ltd., Yongin-Si (KR)

(72) Inventors: KANGBIN JO, Yongin-si (KR); SEUNGHYUN MOON, Yongin-si (KR); GUN HEE KIM, Yongin-si (KR); JAE-KYOUNG KIM, Yongin-si (KR); GYEONG-UB MOON, Yongin-si (KR); GOEUN CHA, Yongin-si (KR); BORAM CHOI, Yongin-si (KR)

(21) Appl. No.: 19/644,165

(22) Filed: Apr. 10, 2026

(30) Foreign Application Priority Data
Apr. 15, 2025 (KR) 10-2025-0048834

(51) Int. Cl. H10K 59/65; H10K 59/122; H10K 59/38; H10K 59/80

(52) U.S. Cl. CPC H10K 59/65; H10K 59/122; H10K 59/38; H10K 59/879

(57) ABSTRACT

Disclosed is a display device which includes a base layer, a circuit layer disposed on the base layer, an element layer disposed on the circuit layer, and including a plurality of light emitting elements and a plurality of light receiving elements adjacent to each other, and an optical control layer including a plurality of lenses overlapping the plurality of light receiving elements in a plan view. The plurality of lenses include a first lens having a first focal length and a second lens having a second focal length different from the first focal length.

### CROSS-REFERENCE TO RELATED APPLICATIONS

This application claims priority under 35 U.S.C. § 119 to Korean Patent Application No. 10-2025-0048834 filed on Apr. 15, 2025, in the Korean Intellectual Property Office, the disclosures of which are incorporated by reference herein in their entireties.

### BACKGROUND

Embodiments of the present disclosure described herein relate to an electronic device, and more particularly, to an electronic device including a light receiving element.

Multimedia electronic devices, such as televisions, cellular phones, tablet computers, navigations, or game consoles, include a display device to display an image, and an input sensing device to sense an external input. In particular, electronic devices additionally include a function for sensing biometric information of a user.

The biometric information of the user is recognized by using a capacitive manner of sensing a change in capacitance formed between electrodes, an optical sensing manner for sensing an incident light through an optical sensor, and an ultrasonic manner for sensing vibration by utilizing a piezoelectric body.

### SUMMARY

Embodiments of the present disclosure are to sense an external gesture through a light receiving element disposed in a display panel.

According to an embodiment of the present disclosure, a display device includes a base layer, a circuit layer disposed on the base layer, an element layer disposed on the circuit layer and including a plurality of light emitting elements and a plurality of light receiving elements adjacent to each other, and an optical control layer including a plurality of lenses overlapping the plurality of light receiving elements in a plan view. The plurality of lenses includes a first lens having a first focal length, and a second lens having a second focal length different from the first focal length.

According to an aspect of the present disclosure, a display device includes a base layer, a circuit layer disposed on the base layer, an element layer disposed on the circuit layer, and including a plurality of light emitting elements and a plurality of light receiving elements disposed on a same layer. The plurality of light emitting elements include a first light emitting element to emit first light having a first wavelength range, and a second light emitting element to emit second light having a second wavelength range different from the first wavelength range. A light receiving element of the plurality of light receiving elements receives the first light, and the first wavelength range is equal to or greater than 750 nm and equal to or less than 1,000 nm.

According to another aspect of the present disclosure, an electronic device includes a display device to display an image, and a processor to provide image data to the display device.

The display device includes a base layer, a circuit layer disposed on the base layer, an element layer disposed on the circuit layer, and including a plurality of light emitting elements and a plurality of light receiving elements adjacent to each other, and an optical control layer including a plurality of lenses overlapping the plurality of light receiving elements in a plan view. The plurality of lenses includes a first lens having a first focal length, and a second lens having a second focal length different from the first focal length.

### BRIEF DESCRIPTION OF THE FIGURES

The above and other features of the present disclosure will become apparent by describing in detail embodiments thereof with reference to the accompanying drawings.

FIG. 1 is a block diagram of an electronic device according to an embodiment of the present disclosure.

FIG. 2 is schematic views illustrating embodiments of various electronic devices.

FIG. 3 is a perspective view of an electronic device according to an embodiment of the present disclosure.

FIG. 4 is an exploded perspective view of an electronic device according to an embodiment of the present disclosure.

FIG. 5 is a cross-sectional view of a display module illustrated in FIG. 4 according to an embodiment of the present disclosure.

FIG. 6 is a block diagram of an electronic device according to an embodiment of the present disclosure.

FIG. 7A is a circuit diagram of a pixel and a sensor according to an embodiment of the present disclosure.

FIG. 7B is a waveform diagram to describe operations of the pixel and the sensor illustrated in FIG. 7A.

FIG. 8 is an enlarged plan view illustrating a partial region of a display panel according to an embodiment of the present disclosure.

FIG. 9A is a cross-sectional view of a display device taken along line I-I′ illustrated in FIG. 8 according to an embodiment of the present disclosure.

FIG. 9B is a cross-sectional view of a display device taken along line I-I′ illustrated in FIG. 8 according to an embodiment of the present disclosure.

FIG. 10 is a cross-sectional view of a display device taken along line II-II′ illustrated in FIG. 8 according to an embodiment of the present disclosure.

FIG. 11A is a view schematically illustrating a plurality of light receiving elements and lenses according to the present disclosure.

FIG. 11B is a view to describe FIG. 11A.

FIGS. 12A, 12B, 12C, 12D, and 12E are views illustrating the sharpness of a gesture based on the distance between gestures.

### DETAILED DESCRIPTION

While the present disclosure is susceptible to various modifications and alternative forms, specific embodiments thereof are shown by way of example in the drawings and will be described herein in detail. It should be understood, however, that there is no intent to limit the present disclosure to the particular forms disclosed, but on the contrary, the present disclosure is to cover all modifications, equivalents, and alternatives falling within the spirit and scope of the present disclosure.

In the specification, the expression that a first component (or region, layer, or part) is “on”, “connected to”, or “coupled to” a second component refers to that the first component is directly on, connected to, or coupled to the second component or refers to that a third component is interposed therebetween.

The same reference numeral will be assigned to the same component. In addition, in drawings, thicknesses, proportions, and dimensions of components may be exaggerated to describe the technical features effectively. The term “and/or” includes any and all combinations of one or more of associated components.

Although the terms “first”, or “second” may be used to describe various components, the components should not be construed as being limited by the terms. The terms are only used to distinguish one component from another component. For example, without departing from the scope and spirit of the present disclosure, a first component may be referred to as a second component, and similarly, the second component may be referred to as the first component. The singular forms are intended to include the plural forms unless the context clearly indicates otherwise.

In addition, the terms “under”, “at a lower portion”, “above”, “an upper portion” are used to describe the relationship between components illustrated in drawings. The terms are relative and will be described with reference to a direction indicated in the drawing.

It will be further understood that the terms “comprise,” “include,” or “including,” or “have” or “having” specify the presence of stated features, numbers, steps, operations, components, parts, or the combination thereof, but do not preclude the presence or addition of one or more other features, numbers, steps, operations, components, parts, and/or the combination thereof.

In the specification, the wording “a certain member is directly disposed” may refer to that an additional layer, film, region, or plate is absent between a part, such as a layer, film, region, or plate, and another part, such as another layer, film, region, or plate. For example, “directly contact” may mean that two layers or two members are disposed without using an additional member, such as an adhesive member, between the layers or members.

Unless defined otherwise, all terms (including technical terms and scientific terms) used in the specification have the same meaning as commonly understood by one skilled in the art to which the present disclosure belongs. Furthermore, terms such as terms defined in the dictionaries commonly used should be interpreted as having a meaning consistent with the meaning in the context of the related technology, and should not be interpreted in ideal or overly formal meanings unless explicitly defined herein.

Hereinafter, a display device according to an embodiment will be described with reference to the drawings.

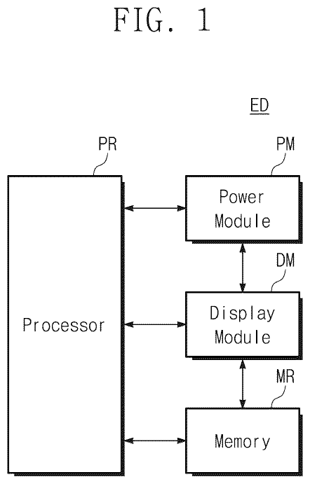

FIG. 1 is a block diagram of an electronic device ED according to an embodiment of the present disclosure.

Referring to FIG. 1, the electronic device ED according to an embodiment may include a display module DM, a processor PR, a memory MR, and a power module PM.

The processor PR may include one or more processors and may include at least one a central processing unit (CPU), an application processor (AP), a graphic processing unit (GPU), a communication processor (CP), an image signal processor (ISP), or a controller.

The memory MR may store data information necessary for the operation of the processor PR or the display module DM. When the processor PR runs the application stored in the memory MR, an image data signal and/or an input control signal may be transmitted to the display module DM, and the display module DM may process the transmitted signal and output the image information through the display screen. The display module DM may include a display panel to display an image.

The power module PM may include a power converting module. The power module PM may include a power supply module, such as a power adaptor or a battery device, and a power converting module to convert the power supplied from the power supply module into power necessary for the operation of the electronic device ED.

At least one of components of the electronic device ED described above may be included in a display module according to embodiments to be described below and a display device including the display module according to an embodiment. In addition, some of individual modules functionally included in one module may be included in the display device, and others of the individual modules may be provided separately from the display device. For example, the display device may include the display module DM, and the processor PR, the memory MR, and the power module PM may be provided in the form of another device in the electronic device ED instead of the display device.

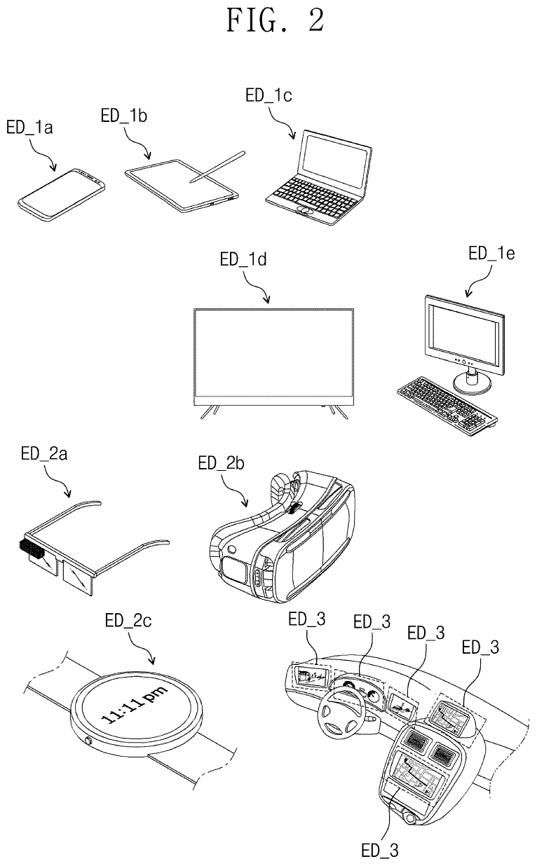

FIG. 2 is schematic diagrams illustrating embodiments of various electronic devices.

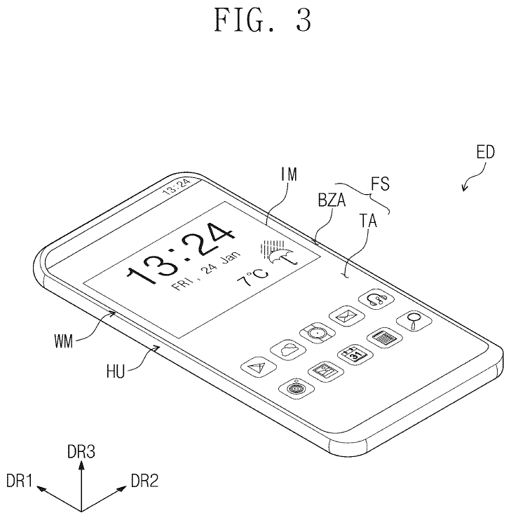

Referring to FIG. 2, various electronic devices including the display module according to an embodiment of the present disclosure may include a wearable electronic device such as smart glasses ED_2a, a head mounted display ED_2b, and a smart watch ED_2c, and a vehicle electronic device ED_3, such as a center information display (CID), which is disposed in an instrument panel, a center fascia, and a dashboard of a vehicle, or a room mirror display, as well as an electronic device for image display, such as a smartphone ED_1a, a tablet PC ED_1b, a laptop computer ED_1c, a television ED_1d and a desk monitor ED_1e. The electronic device ED according to an embodiment of the present disclosure may be a cellular phone as illustrated in FIG. 3, but the present disclosure is not limited thereto.

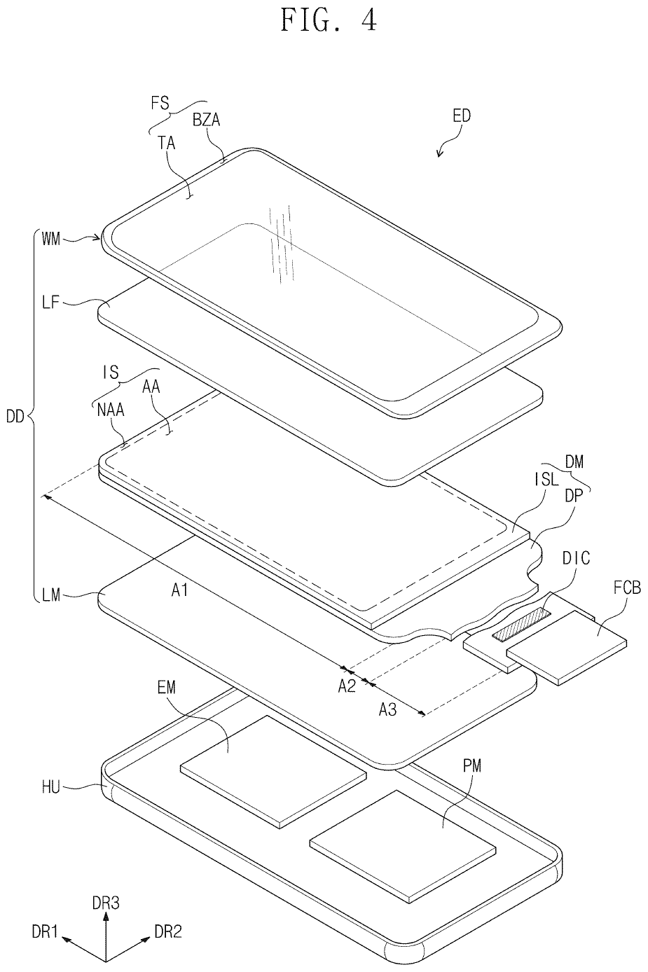

FIG. 3 is a perspective view of an electronic device ED according to an embodiment of the present disclosure. FIG. 4 is an exploded perspective view of the electronic device ED according to an embodiment of the present disclosure.

The electronic device ED may be a device, which is activated, in response to an electrical signal. The electronic device ED may include various embodiments. For example, the electronic device ED may be applied to an electronic device such as a cellular phone, a smart watch, a tablet personal computer (PC), a laptop computer, or a smart television. According to the present disclosure, the electronic device ED is not limited to the examples. The electronic device ED may be applied to other electronic devices, as long as other electronic devices do not deviate from the concept of the present disclosure. According to an embodiment a cellular phone is illustrated as an example of the electronic device ED.

The electronic device ED may display an image IM on a display surface FS, which is parallel to each of a first direction DR1 and a second direction DR2, in a third direction DR3. The display surface FS for displaying the image IM may correspond to a front surface of a display device DD. The image IM may include a still image as well as a video (or a moving picture). A watch and icons are illustrated in FIG. 3 as an example of the image IM.

According to an embodiment, a front surface (or a top surface) and a rear surface (or a bottom surface) of each of members are defined based on a direction in which the image IM is displayed. The front surface and the rear surface are opposite to each other in the third direction DR3, and a normal direction to each of the front surface and the rear surface may parallel to the third direction DR3. A separation distance between the front surface and the rear surface in the third direction DR3 may correspond to a thickness of the display device DD in the third direction DR3. In the present disclosure, the wording “when viewed in a plan view” or “in a plan view” may refer to the state when viewed in the third direction DR3. The first direction DR1, the second direction DR2, and the third direction DR3 may be relative concepts and may be changed to different directions.

The electronic device ED may sense an external input applied from the outside. The external input may include various types of inputs which are provided from the outside of the electronic device ED. For example, as well as a contact by a part, a user hand, of a body, the external input may include an external input (for example, a hovering input) which is applied in a state in which the user hand approaches the electronic device ED or is adjacent to the electronic device ED within a specific distance. In addition, the external input may have various types such as force, pressure, a temperature, and a light.

The electronic device ED includes a window WM and a housing HU. According to an embodiment, the window WM is coupled to the housing HU to form an outer appearance of the electronic device ED.

The window WM may be divided into a transmission region TA and a bezel region BZA. The display surface FS of the electronic device ED may correspond to the transmission region TA and the bezel region BZA of the window WM.

The transmission region TA may be a region for displaying the image IM. The transmission region TA may be an optically transparent region. The user views the image through the transmission region TA.

According to an embodiment, the transmission region TA has vertexes in a rounded-rectangular shape. However, the shape is provided for the illustrative purpose. For example, the transmission region TA may have various shapes, and not limited to any one embodiment.

The bezel region BZA may have a light transmittance lower than a light transmittance of the transmission region TA. For example, the bezel region BZA may be provided in the form of a region printed with a material including a specific color.

The bezel region BZA may be adjacent to the transmission region TA. The bezel region BZA may surround the transmission region TA. Accordingly, the shape of the transmission region TA may be defined substantially by the bezel region BZA. However, this is provided only for the illustrative purpose. For example, the bezel region BZA may be only disposed adjacent to one side of the transmission region TA or may be omitted.

Referring to FIGS. 3 and 4, the electronic device ED may include the display device DD, an electronic module EM, the power module PM, and the housing HU. Although FIG. 4 illustrates the electronic device ED in brief, and the electronic device ED may further include a mechanism structure (e.g., a hinge) to control an operation (e.g., folding or rolling) of the display device DD.

The display device DD includes the window WM, an optical film LF, the display module DM, a lower member LM, a driving chip DIC, or a flexible circuit board FCB.

The window WM may be disposed on the display module DM. The window WM may protect the display module DM. The window WM may include an optically transparent material. For example, the window WM may include glass, sapphire and plastic. The image provided to the display module DM may be provided to the user through the window WM.

The window WM may have a single-layer structure or a multi-layer structure. For example, the window WM may include a plurality of plastic films bonded to each other or may have a glass substrate and a plastic film bonded to each other.

The optical film LF may be disposed under the window WM. The optical film LF reduces the reflectance of an external light incident from above the window WM. The optical film LF may include a retarder and a polarizer. The retarder may be provided in a film type or a liquid crystal coating type, and may include a λ/2 retarder and/or λ/4 a retarder. The polarizer may be in a film type or a liquid crystal coating type. The film type polarizer may include a stretched synthetic resin film, and the liquid crystal coating type polarizer may include liquid crystals aligned in a specific array. The retarder and the polarizer may be implemented with one polarization film. The optical film LF may further include a protective film disposed at an upper portion or a lower portion of a polarizing film.

The display module DM may be disposed under the optical film LF. The display module DM includes a front surface IS including an active region AA and a peripheral region NAA. The active region AA may be activated in response to an electrical signal. According to an embodiment, the active region AA may be a region for displaying the image IM while sensing the external input.

The transmission region TA may be overlapped with at least a portion of the active region AA. Accordingly, the user may view the image IM through the transmission region TA or provide the external input through the transmission region TA. However, this is provided only for the illustrative purpose. For example, in the active region AA, the region for displaying the image IM may be separated from the region for sensing the external input. However, the present disclosure is not limited to any one embodiment.

The peripheral region NAA may be a region covered by the bezel region BZA. The peripheral region NAA is adjacent to the active region AA. The peripheral region NAA may surround the active region AA. The peripheral region NAA may include a driving circuit or a driving line disposed to drive the active region AA.

According to the present disclosure, the display module DM may include a first region A1, a second region A2, and a third region A3 arranged in the first direction DR1. The first region A1 may include an active region AA. In this specification, a remaining region of the first region A1 except for the active region AA, the second region A2, and the third region A3 may correspond to the peripheral region NAA.

The third region A3 may be a region for mounting the driving chip DIC, and may include pads disposed to be adjacent to end. The flexible circuit board FCB may be disposed on the pads of the third region A3 and may be electrically connected to the display module DM. Although not illustrated, the electronic device ED according to the present disclosure may further include a cover layer disposed on the display module DM. The details thereof will be described later.

According to the present disclosure, the second region A2 of the display module DM may be bent such that the third region A3 faces the rear surface of the display module DM. In addition, the driving chip DIC and the flexible circuit board FCB may be disposed under the first region A1. The cover layer may be bent while the second region A2 of the display module DM is bent.

The display module DM may include the display panel DP and an input sensing layer ISL. The display panel DP according to an embodiment of the present disclosure may be a liquid crystal display panel or an emissive-type display panel and the present disclosure is not particularly limited thereto. For example, the emissive-type display panel may be an organic light emitting display panel or a quantum dot light emitting display panel. The light emitting layer of the organic light emitting display panel may include an organic light emitting material. A light emitting layer of the quantum dot light emitting display panel may include a quantum dot, or a quantum rod.

The display panel DP may be flexible. The term “Flexible” refers to a bendable property and may include everything from a fully folded structure to a partially bendable structure. For example, the display panel DP may be a curved display panel or a foldable display panel. However, the present disclosure is not limited thereto. The display panel DP may be a rigid display panel.

The input sensing layer ISL may be directly disposed on the display panel DP. As illustrated in FIG. 4, the input sensing layer ISL may be directly disposed on the display panel DP. In other words, the input sensing layer ISL may be formed on the display panel DP through a subsequent process, and an adhesive film may not be disposed between the input sensing layer ISL and the display panel DP. However, the present disclosure is not limited thereto. The adhesive film may be interposed between the input sensing layer ISL and the display panel DP. In other words, after fabricating the input sensing layer ISL through a process separate from a process for the display panel DP, the input sensing layer ISL may be fixed on a top surface of the display panel DP through the adhesive film.

The input sensing layer ISL may sense an external input that is applied from the outside. As described above, the input sensing layer ISL may sense an external input provided on the window WM.

The flexible circuit board FCB may be disposed at one side of the display panel DP. In detail, the flexible circuit board FCB may be overlapped with the end portion of the third region A3 of the display panel DP, while being disposed on the display panel DP. Although one flexible circuit board FCB is illustrated according to an embodiment, the present disclosure is not limited thereto. A plurality of flexible circuit boards FCB may be provided.

The driving chip DIC may be disposed in the third region A3 of the display module DM. The driving chip DIC may be disposed on the display panel DP. The driving chip DIC may include a driving element to drive a pixel of the display panel DP. The driving chip DIC may include a driving circuit, and the driving circuit may include an integrated circuit. The driving circuit may include a driving controller, a data driver, or a voltage generator.

Although not illustrated, the flexible circuit board FCB may further include an input circuit board electrically connected to the input sensing layer ISL. The input circuit board may connect the input sensing layer ISL to a main circuit board. According to an embodiment, the input circuit board may be provided in the form of a flexible circuit film to connect the input sensing layer ISL to the main circuit board. The input circuit board provides an electrical signal for driving the input sensing layer ISL to the input sensing layer ISL. The electrical signal may be generated from the input circuit board or may be generated from the main circuit board.

The lower member LM may be disposed under the display panel DP. The lower member LM may include a protective film to protect the display panel DP, a support member to support the display panel DP, or a digitizer.

The electronic module EM and the power module PM may be disposed under the display module DM. The electronic module EM and the power module PM may be electrically connected through a separate circuit board.

The power module PM may supply power necessary for operating the electronic device ED. For example, the power module PM may include a typical battery module.

The electronic module EM may include a control module, a wireless communication module, an image input module, a sound input module, a sound output module, a memory, or an external interface. The electronic module EM may include the main circuit board, and the modules may be mounted on the main circuit board or may be electrically connected with the main circuit board through a flexible circuit board. The electronic module EM is electrically connected with the power module PM.

Although not separately illustrated, the electronic device ED may further include an electro-optical module. The electro-optical module may be an electronic part that outputs or receives an optical signal. The electro-optical module may include a camera module and/or a proximity sensor. The camera module may photograph an external image through a partial region of the display panel DP.

The housing HU illustrated in FIG. 4 is coupled to the display device DD, in particular, the window WM to receive the other modules. Although the housing HU is illustrated to have an integral form, the present disclosure is not limited thereto. The housing HU may include a plurality of portions (e.g., a side edge part and a bottom part) coupled to each other. The housing HU may protect the display module DM received in the inner space from an external impact, and may prevent foreign substances or moisture from penetrating into the display module DM.

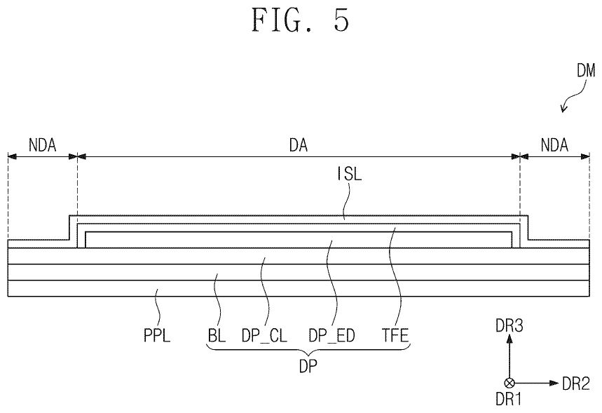

FIG. 5 is a cross-sectional view of the display module DM illustrated in FIG. 4 according to an embodiment of the present disclosure.

Referring to FIG. 5, the display module DM may include the input sensing layer ISL, the display panel DP, and a panel protecting layer PPL. The display panel DP may include a base layer BL, a circuit layer DP_CL, a display layer (or an element layer) DP_ED, and an encapsulating layer TFE, which are disposed on the base layer BL. The input sensing layer ISL may be disposed on the encapsulating layer TFE.

The display panel DP may include a display region DA and a non-display region NDA. The display region DA of the display panel DP may correspond to the transmission region TA illustrated in FIG. 3, and the non-display region NDA may correspond to the bezel region BZA illustrated in FIG. 3.

The base layer BL may include at least one plastic film. The base layer BL may serve as a flexible board, and may include a plastic substrate, a glass substrate, a metal substrate, or an organic/inorganic composite substrate.

The circuit layer DP_CL may include at least one intermediate insulating layer and a circuit layer. The intermediate insulating layer includes at least one intermediate inorganic layer and at least one intermediate organic layer. A circuit device may include signal lines and a pixel driving circuit.

The display layer DP_ED may include a plurality of organic light emitting diodes. The display layer DP_ED may further include an organic layer such as a pixel defining layer.

The encapsulating layer TFE may seal the display layer DP_ED. The encapsulating layer TFE may be disposed on the display layer DP_ED. The encapsulating layer TFE may be overlapped with the display region DA. The encapsulating layer TFE may be overlapped with at least some of the non-display region NDA. For example, the encapsulating layer TFE may include a thin film encapsulating layer. The thin film encapsulating layer may include a stack structure of an inorganic layer, an organic layer, and an inorganic layer. The encapsulating layer TFE may protect the display layer DP_ED from foreign substances such as moisture, oxygen, and dust particles. However, the present disclosure is not limited thereto. The encapsulating layer TFE may further include an additional insulating layer in addition to the thin film encapsulating layer.

According to an embodiment of the present disclosure, an encapsulation substrate may be provided in place of the encapsulating layer TFE. In this case, the encapsulating substrate may face the base layer BL, and the circuit layer DP_CL and the display layer DP_ED may be interposed between the encapsulating substrate and the base layer BL.

The input sensing layer ISL may be directly disposed on the display panel DP. In this specification, component “A” is directly disposed on component “B” refers to that a separate layer is not disposed between component “A” and component “B”. According to an embodiment, the input sensing layer ISL may be fabricated through a process subsequent to a process for the display panel DP. However, the technical spirit of the present disclosure is not limited thereto, and the input sensing layer ISL, which is provided in the form of an individual panel, may be coupled to the display panel DP through an adhesive layer. For example, the input sensing layer ISL may be omitted.

The panel protecting layer PPL may be disposed under the display panel DP. The panel protecting layer PPL may protect a lower portion of the display panel DP. The panel protecting layer PPL may include a flexible plastic material. For example, the panel protecting layer PPL may include polyethylene terephthalate (PET).

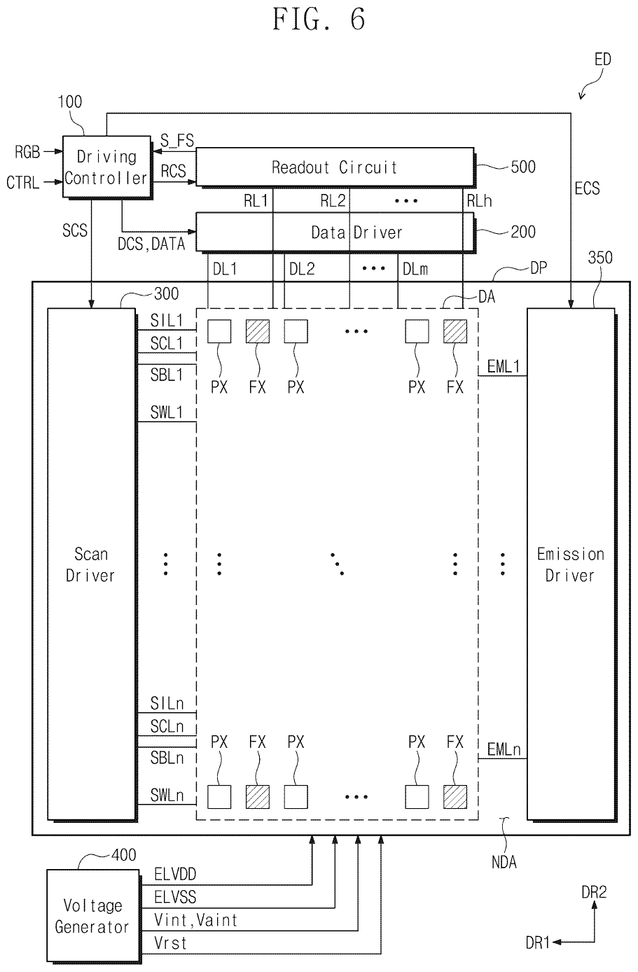

FIG. 6 is a block diagram of an electronic device ED according to an embodiment of the present disclosure.

Referring to FIG. 6, the electronic device ED includes the display panel DP, a panel driver, and a driving controller 100. According to an embodiment of the present disclosure, the panel driver includes a data driver 200, a scan driver 300, an emission driver 350, a voltage generator 400, and a readout circuit 500.

The driving controller 100 receives an image signal RGB and a control signal CTRL. The driving controller 100 generates image data DATA by transforming a data format of the image signal RGB to be matched to the specification for an interface with the data driver 200. The driving controller 100 outputs a first control signal SCS, a second control signal ECS, a third control signal DCS, and a fourth control signal RCS.

The data driver 200 receives the third control signal DCS and the image data DATA from the driving controller 100. The data driver 200 transforms the image data DATA into data signals, and outputs the data signals to a plurality of data lines DL1 to DLm to be described later. The data signals refer to analog voltages corresponding to grayscale values of the image data DATA. According to an embodiment of the present disclosure, the data driver 200 may be embedded in the driving chip DIC illustrated in FIG. 4.

The scan driver 300 receives the first control signal SCS from the driving controller 100. The scan driver 300 may output scan signals to scan lines in response to the first control signal SCS.

The voltage generator 400 generates voltages necessary for an operation of the display panel DP. According to an embodiment, the voltage generator 400 generates a first driving voltage ELVDD, a second driving voltage ELVSS, a first initializing voltage Vint, a second initializing voltage Vaint, and a reset voltage Vrst.

The display panel DP may include a display region DA corresponding to the transmission region TA (illustrated in FIG. 4) and the non-display region NDA corresponding to the bezel region BZA (illustrated in FIG. 4).

The display panel DP may include a plurality of pixels PX disposed in the display region DA and a plurality of sensors FX disposed in the display region DA. According to an embodiment of the present disclosure, each of the plurality of sensors FX may be disposed between two adjacent pixels PX. The plurality of pixels PX and the plurality of sensors FX may be alternately disposed in the first and second directions DR1 and DR2. However, the present disclosure is not limited thereto. In other words, at least two pixels PX may be interposed between two sensors, which are adjacent to each other when viewed in the first direction DR1, of the plurality of sensors FX, or at least two pixels PX may be disposed between two sensors, which are adjacent to each other when viewed in the second direction DR2, of the plurality of sensors FX.

The display panel DP further includes initializing scan lines SIL1 to SILn, compensating scan lines SCL1 to SCLn, write scan lines SWL1 to SWLn, black scan lines SBL1 to SBLn, emission control lines EML1 to EMLn, the data lines DL1 to DLm, and readout lines RL1 to RLh. The initializing scan lines SIL1 to SILn, the compensating scan lines SCL1 to SCLn, the write scan lines SWL1 to SWLn, the black scan lines SBL1 to SBLn, and the emission control lines EML1 to EMLn extend in the first direction DR1. The initializing scan lines SIL1 to SILn, the compensating scan lines SCL1 to SCLn, the write scan lines SWL1 to SWLn, the black scan lines SBL1 to SBLn, and the emission control lines EML1 to EMLn are arranged to be spaced from each other in the second direction DR2. The data lines DL1 to DLm and readout lines RL1 to RLh extend in the second direction DR2 and are arranged to be spaced from each other in the first direction DR1. Herein, ‘n’, ‘m’, and ‘h’ are a natural number of 1 or more.

The plurality of pixels PX are electrically connected to the initializing scan lines SIL1 to SILn, the compensating scan lines SCL1 to SCLn, the write scan lines SWL1 to SWLn, the black scan lines SBL1 to SBLn, the emission control lines EML1 to EMLn, and the data lines DL1 to DLm. For example, each of the plurality of pixels PX may be electrically connected to four scan lines. However, the number of scan lines connected to each pixel PX is not limited thereto and may be varied.

The plurality of sensors FX may be electrically connected to the write scan lines SWL1 to SWLn and the readout lines RL1 to RLh, respectively. Each of the plurality of sensors FX may be electrically connected with one scan line. However, the present disclosure is not limited thereto. The number of scan lines connected to each sensor FX may be varied. According to an embodiment of the present disclosure, the number of readout lines RL1 to RLh may be less than or equal to the number of data lines DL1 to DLm. For example, the number of readout lines RL1 to RLh may correspond to ½, ¼, or ⅛ of the number of data lines DL1 to DLm.

The scan driver 300 may be disposed in the non-display region NDA of the display panel DP. The scan driver 300 receives the first control signal SCS from the driving controller 100. The scan driver 300 outputs initializing scan signals to the initializing scan lines SIL1 to SILn and may output compensating scan signals to the compensating scan lines SCL1 to SCLn, in response to the first control signal SCS. In addition, the scan driver 300 may output write scan signals to the write scan lines SWL1 to SWLn and may output black scan signals to the black scan lines SBL1 to SBLn, in response to the first control signal SCS. In an embodiment, the scan driver 300 may include a first scan driver and a second scan driver. The first scan driver may output the initializing scan signals and the compensating scan signals, and the second scan driver may output the write scan signals and the black scan signals.

The emission driver 350 may be disposed in the non-display region NDA of the display panel DP. The emission driver 350 receives the second control signal ECS from the driving controller 100. The emission driver 350 may output emission control signals to the emission control lines EML1 to EMLn in response to the second control signal ECS. In an embodiment, the scan driver 300 may be connected to the emission control lines EML1 to EMLn. In this case, the emission driver 350 may be omitted, and the scan driver 300 may output the emission control signals to the emission control lines EML1 to EMLn.

The readout circuit 500 receives a fourth control signal RCS from the driving controller 100. The readout circuit 500 may receive sensing signals from the readout lines RL1 to RLh, in response to the fourth control signal RCS. The readout circuit 500 may process the sensing signals received from the readout lines RL1 to RLh and may provide sensing signals S_FS, which is processed, to the driving controller 100. The driving controller 100 may recognize biometric information based on the sensing signals S_FS.

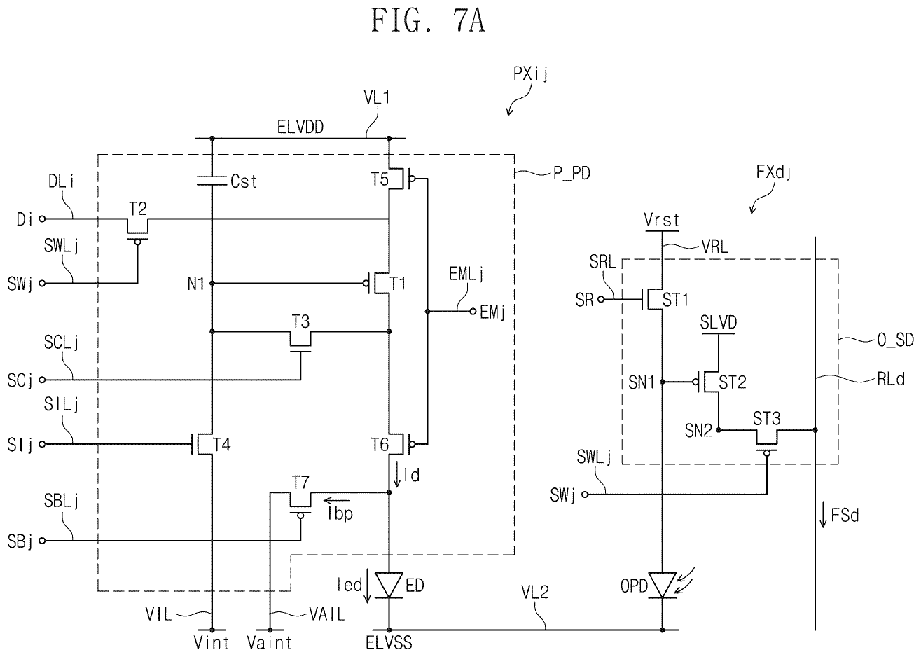

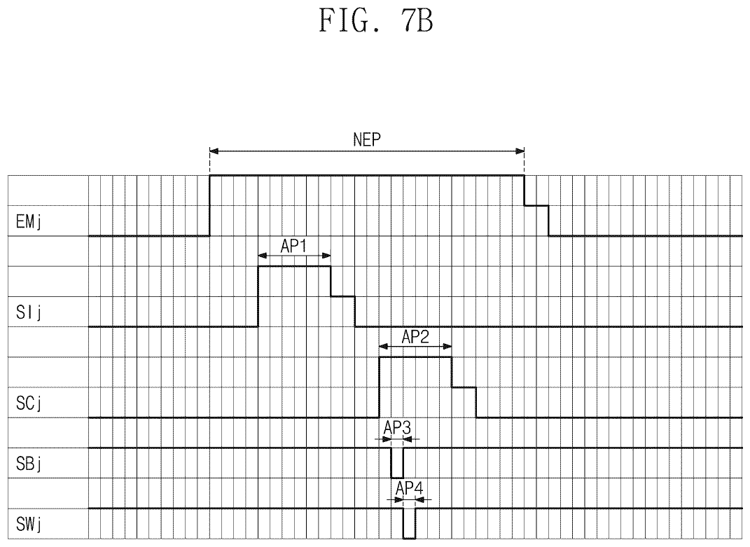

FIG. 7A is a circuit diagram illustrating a pixel PXij and a sensor FXdj according to an embodiment of the present disclosure, and FIG. 7B is a waveform diagram to describe the operations of the pixel PXij and the sensor FXdj illustrated in FIG. 7A.

FIG. 7A illustrates an equivalent circuit diagram of one pixel PXij of the plurality of pixels PX illustrated in FIG. 6. Since each of the plurality of pixels PX has the same circuit structure, the pixel PXij will be representatively described, and the repetition of the description about remaining pixels PX may be omitted to avoid redundancy. In addition, FIG. 7A illustrates an equivalent circuit diagram of one sensor FXdj of the plurality of sensors FX illustrated in FIG. 6. Since each of the plurality of sensors FX has the same circuit structure, the sensor FXdj will be representatively described, and the repetition of the description about remaining sensors FX may be omitted to avoid redundancy. Herein, ‘i’, ‘j’ and ‘d’ are a natural number of 1 or more.

Referring to FIG. 7A, the pixel PXij is connected to an i-th data line DLi among the data lines DL1 to DLm, a j-th initializing scan line SILj among the initializing scan lines SIL1 to SILn, a j-th compensating scan line SCLj among the compensating scan lines SCL1 to SCLn, a j-th write scan line SWLj among the write scan lines SWL1 to SWLn, a j-th black scan line SBLj among the black scan lines SBL1 to SBLn, and a j-th emission control line EMLj among the emission control lines EML1 to EMLn.

The pixel PXij includes a light emitting element ED and a pixel driving circuit P_PD. The light emitting element ED may be a light emitting diode. According to an embodiment of the present disclosure, the light emitting element ED may be an organic light emitting diode including an organic emission layer.

The pixel driving circuit P_PD includes first to seventh transistors T1 to T7 and one capacitor Cst. At least one of the first to seventh transistors T1 to T7 may be a transistor having a low-temperature polycrystalline silicon (LTPS) semiconductor layer. Some of the first to seventh transistors T1 to T7 may be P-type transistors, and the remaining transistors may be N-type transistors. At least one of the first to seventh transistors T1 to T7 may be a transistor having an oxide semiconductor layer. For example, the third and fourth transistors T3 and T4 may be oxide semiconductor transistors, and the first, second, and fifth to seventh transistors T1, T2, and T5 to T7 may be LTPS transistors. The third and fourth transistors T3 and T4 may be NMOS transistors.

The configuration of the pixel driving circuit P_PD according to an embodiment of the present disclosure is not limited to the example illustrated in FIG. 7A. The pixel driving circuit P_PD illustrated in FIG. 7A is merely one example, and the configuration of the pixel driving circuit P_PD may be implemented in a modified form. For example, all of the first, second, and fifth to seventh transistors T1, T2, and T5 to T7 may be P-type transistors or N-type transistors.

The j-th initializing scan line SILj, the j-th compensating scan line SCLj, the j-th write scan line SWLj, the j-th black scan line SBLj, and the j-th emission control line EMLj may transmit a j-th initializing scan signal SIj, a j-th compensating scan signal SCj, a j-th write scan signal SWj, a j-th black scan signal SBj, and a j-th emission control signal EMj to the pixel PXij, respectively. The i-th data line DLi is to transmit the i-th data signal Di to the pixel PXij. The i-th data signal Di may have a voltage level corresponding to the image signal RGB input to the display device DD (see FIG. 4).

According to an embodiment of the present disclosure, the pixel PXij may be connected to first and second driving voltage lines VL1 and VL2, and first and second initializing voltage lines VIL and VAIL. The first driving voltage line VL1 may be to transmit the first driving voltage ELVDD to the pixel PXij, and the second driving voltage line VL2 may be to transmit the second driving voltage ELVSS to the pixel PXij. In addition, the first initializing voltage line VIL may be to transmit the first initializing voltage Vint to the pixel PXij, and the second initializing voltage line VAIL may be to transmit the second initializing voltage Vaint to the pixel PXij.

The first transistor T1 is connected between the first driving voltage line VL1, which receives the first driving voltage ELVDD, and the light emitting element ED. The first transistor T1 includes a first electrode connected to the first driving voltage line VL1 via the fifth transistor T5, a second electrode connected to an anode electrode of the light emitting element ED via the sixth transistor T6, and a third electrode (for example, a gate electrode) connected to one terminal (for example, a first node N1) of the capacitor Cst. The first transistor T1 may receive an i-th data signal Di received through the i-th data line DLi depending on a switching operation of the second transistor T2, and may supply a driving current Id to the light emitting element ED.

The second transistor T2 is connected between the i-th data line DLi and the first electrode of the first transistor T1. The second transistor T2 includes a first electrode connected to the i-th data line DLi, a second electrode connected to the first electrode of the first transistor T1, and a third electrode (for example, a gate electrode) connected to the j-th write scan line SWLj. The second transistor T2 may be turned on in response to the j-th write scan signal SWj received through the j-th write scan line SWLj, and may transmit the i-th data signal Di, which is received through the i-th data line DLi, to the first electrode of the first transistor T1.

The third transistor T3 is connected between the second electrode of the first transistor T1 and the first node N1. The third transistor T3 includes a first electrode connected to the third electrode of the first transistor T1, a second electrode connected to the second electrode of the first transistor T1, and a third electrode (for example, a gate electrode) connected to the j-th compensating scan line SCLj. The third transistor T3 may be turned on in response to the j-th compensating scan signal SCj received through the j-th compensating scan line SCLj, and may connect the third electrode and the second electrode of the first transistor T1 to each other to diode-connect the first transistor T1.

The fourth transistor T4 is connected between the first initializing voltage line VIL for applying the first initializing voltage Vint and the first node N1. The fourth transistor T4 includes a first electrode connected to the first initializing voltage line VIL for applying the first initializing voltage Vint, a second electrode connected to the first node N1, and a third electrode (for example, a gate electrode) connected to the j-th initializing scan line SILj. The fourth transistor T4 is turned on in response to the j-th initializing scan signal SIj received through the j-th initializing scan line SILj. The fourth transistor T4, which is turned on, transmits the first initializing voltage Vint to the first node N1, thereby initializing a potential (that is, the potential of the first node N1) of the third electrode of the first transistor T1.

The fifth transistor T5 includes a first electrode connected to the first driving voltage line VL1, a second electrode connected to the first electrode of the first transistor T1, and a third electrode (for example, a gate electrode) connected to the j-th emission control line EMLj.

The sixth transistor T6 includes a first electrode connected to the second electrode of the first transistor T1, a second electrode connected to the anode electrode of the light emitting element ED, and a third electrode (for example, a gate electrode), connected to the j-th emission control line EMLj.

The fifth and sixth transistors T5 and T6 are simultaneously turned on in response to the j-th emission control signal EMj received through the j-th emission control line EMLj. The first driving voltage ELVDD applied through the fifth transistor T5, which is turned on, may be compensated through the diode-connected first transistor T1 and may be transmitted to the light emitting element ED.

The seventh transistor T7 includes a first electrode connected to the second initializing voltage line VAIL for transmitting the second initializing voltage Vaint, a second electrode connected to the second electrode of the sixth transistor T6, and a third electrode (for example, a gate electrode) connected to the j-th black scan line SBLj. The second initializing voltage Vaint may have a voltage level equal to or lower than the first initializing voltage Vint.

The seventh transistor T7 is turned on in response to the j-th black scan signal SBj received through the j-th black scan line SBLj. The second initializing voltage Vaint applied through the seventh transistor T7, which is turned on, may be transmitted to the anode electrode of the light emitting element ED. Accordingly, the anode electrode of the light emitting element ED may be initialized with the second initializing voltage Vaint.

A first terminal of the capacitor Cst is connected to the third electrode of the first transistor T1 as described above, and a second terminal of the capacitor Cst is connected to the first driving voltage line VL1. A cathode electrode of the light emitting element ED may be connected to the second driving voltage line VL2 for transmitting the second driving voltage ELVSS. The second driving voltage ELVSS may have a voltage level lower than a voltage level of the first driving voltage ELVDD. According to an embodiment of the present disclosure, the second driving voltage ELVSS may have the voltage level lower than voltage levels of the first and second initializing voltages Vint and Vaint.

Referring to FIGS. 7A and 7B, the j-th emission control signal EMj has a high level during a non-emission period NEP. Within the non-emission period NEP, the j-th initializing scan signal SIj is activated. When the j-th initializing scan signal SIj having the high level is provided through the j-th initializing scan line SILj during an activation period (hereinafter, a first activation period) AP1 of the j-th initializing scan signal SIj, the fourth transistor T4 is turned on in response to the j-th initializing scan signal SIj having the high level. The first initializing voltage Vint is transmitted to the third electrode of the first transistor T1 through the fourth transistor T4 which is turned on, and the first node N1 is initialized with the first initializing voltage Vint. Accordingly, the first activation period AP1 may be defined as an initializing period of a pixel PXij.

Next, when the j-th compensating scan signal SCj is activated, and when the j-th compensating scan signal SCj having a high level is supplied through the j-th compensating scan line SCLj during an activation period AP2 (hereinafter, a second activation period) of the j-th compensating scan signal SCj, the third transistor T3 is turned on. The first transistor T1 is diode-connected by the third transistor T3 turned on and is forward-biased. The first activation period AP1 may be in a non-overlap state with the second activation period AP2.

Within the second activation period AP2, the j-th write scan signal SWj is activated. The j-th write scan signal SWj has a low level during an activation period AP4 (hereinafter, a fourth activation period). During the fourth activation period AP4, the second transistor T2 is turned on in response to the j-th write scan signal SWj having the low level. Then, a compensating voltage “Di-Vth”, which is obtained by subtracting the threshold voltage (Vth) of the first transistor T1 from the i-th data signal Di, which is supplied through the i-th data line DLi, is applied to the third electrode of the first transistor T1. In other words, a potential of the third electrode of the first transistor T1 may be the compensating voltage “Di-Vth”. The fourth activation period AP4 may be overlapped with the second activation period AP2. The duration of the second activation period AP2 may be greater than the duration of the fourth activation period AP4.

The first driving voltage ELVDD and the compensating voltage “Di-Vth” may be applied to both terminals of the capacitor Cst, and charges corresponding to a voltage difference between the both terminals may be stored in the capacitor Cst. In this case, a high-level period of the j-th compensating scan signal SCj may be referred to as a compensating period of the pixel PXij.

Within the second activation period AP2 of the j-th compensating scan signal SCj, the j-th black scan signal SBj is activated. The j-th black scan signal SBj has a low level during an activation period AP3 (hereinafter, a third activation period). During the third activation period AP3, the seventh transistor T7 is turned on by receiving the j-th black scan signal SBj having a low level through the j-th black scan line SBLj. A portion of the driving current Id may flow out as a bypass current Ibp through the seventh transistor T7, by the seventh transistor T7. The third activation period AP3 may be overlapped with the second activation period AP2. The duration of the second activation period AP2 may be greater than the duration of the third activation period AP3. The third activation period AP3 may precede the fourth activation period AP4 and may be in the non-overlap state with the fourth activation period AP4.

When the pixel PXij displays a black image, even if the minimum driving current of the first transistor T1 flows as the driving current Id, the light emitting element ED may emit light. In this case, the pixel PXij is not able to display the black image normally. Accordingly, the seventh transistor T7 in the pixel PXij according to an embodiment of the present disclosure may divert a portion, which serves as the bypass current Ibp, of the minimum driving current of the first transistor T1, to another current path other than a current path toward the light emitting element ED. In this case, the minimum driving current of the first transistor T1 refers to a current flowing through the first transistor T1, under a condition that a gate-to-source voltage (Vgs) of the first transistor T1 is smaller than the threshold voltage (Vth) such that the first transistor T1 is turned off. Under the condition that the first transistor T1 is turned off, the minimum driving current (for example, a current of 10 pA or less) flowing through the first transistor T1 is transmitted to the light emitting element ED, such that an image having a black grayscale level is displayed. When the pixel PXij displays a black image, the influence of the bypass current Ibp on the minimum driving current is relatively significant. However, when an image such as a general image or a white image is displayed, the influence of the bypass current Ibp on the driving current Id is negligible. Accordingly, when the black image is displayed, a current (that is, a light emitting current led), which is obtained by subtracting a current amount of the bypass current Ibp flowing out through the seventh transistor T7 from the driving current Id, is provided to the light emitting element ED to firmly express the black image. Accordingly, the pixel PXij may implement a black grayscale level image using the seventh transistor T7. Accordingly, a contrast ratio may be improved.

Next, the j-th emission control signal EMj supplied from the j-th emission control line EMLj is changed from a high level to a low level. The fifth and sixth transistors T5 and T6 are turned on in response to the j-th emission control signal EMj having a low level. Then, the driving current Id is generated based on the voltage difference between the voltage of the third electrode of the first transistor T1 and the first driving voltage ELVDD, and the driving current Id is supplied to the light emitting element ED through the sixth transistor T6 such that the light emitting current Ied flows through the light emitting element ED.

Referring again to FIG. 7A, the sensor FXdj is connected to a d-th readout line RLd among the readout lines RL1 to RLh, the j-th write scan line SWLj, and a reset control line SRL.

The sensor FXdj includes a light receiving element OPD and a sensor driving circuit O_SD. According to an embodiment of the present disclosure, the light receiving element OPD may be an organic photodiode including a photoelectric conversion layer including an organic material. Although FIG. 7A illustrates the structure that the sensor FXdj includes one light receiving element OPD, the present disclosure is not limited thereto. For example, the sensor FXdj may include a plurality of light receiving elements OPD connected in parallel to each other.

An anode electrode of the light receiving element OPD is connected to a first sensing node SN1, and a cathode electrode of the light receiving element OPD may be connected to the second driving voltage line VL2 which is used to transmit the second driving voltage ELVSS. The cathode electrode of the light receiving element OPD may be electrically connected to the cathode electrode of the light emitting element ED. According to an embodiment of the present disclosure, the cathode electrode of the light receiving element OPD may be integrally formed with the cathode electrode of the light emitting element ED to form a common cathode electrode.

The sensor driving circuit O_SD includes three transistors ST1 to ST3. The three transistors ST1 to ST3 may respectively be a reset transistor ST1, an amplifying transistor ST2, and an output transistor ST3. At least one of the reset transistor ST1, the amplifying transistor ST2, and the output transistor ST3 may be an oxide semiconductor transistor. According to an embodiment of the present disclosure, the reset transistor ST1 may be an oxide semiconductor transistor, and the amplifying transistor ST2 and the output transistor ST3 may be LTPS transistors. However, the present disclosure is not limited thereto. For example, the reset transistor ST1 and the output transistor ST3 may be oxide semiconductor transistors, and the amplifying transistor ST2 may be an LTPS transistor.

In addition, some of the reset transistor ST1, the amplifying transistor ST2, and the output transistor ST3 may be P-type transistors, and remaining transistors may be N-type transistors. According to an embodiment of the present disclosure, the amplifying transistor ST2 and the output transistor ST3 may be PMOS transistors, and the reset transistor ST1 may be an NMOS transistor. However, the present disclosure is not limited thereto. For example, the reset transistor ST1, the amplifying transistor ST2, and the output transistor ST3 may all be N-type transistors or may all be P-type transistors.

A part (for example, the reset transistor ST1) of the reset transistor ST1, the amplifying transistor ST2, and the output transistor ST3 may be a transistor in a type the same as the types of the third and fourth transistors T3 and T4 of the pixel PXij. The amplifying transistor ST2 and the output transistor ST3 may be transistors in types the same as types of the first, second, and fifth to seventh transistors T1, T2, and T5 to T7 of the pixel PXij.

The circuit configuration of the sensor driving circuit O_SD according to the present disclosure is not limited to FIG. 7A. The sensor driving circuit O_SD illustrated in FIG. 7A is provided only for illustrative purpose, and the configuration of the sensor driving circuit O_SD may be modified and implemented.

The reset transistor ST1 includes a first electrode, which receives a reset voltage Vrst, a second electrode connected to the first sensing node SN1, and a third electrode which receives the reset control signal SR. The reset transistor ST1 may reset a potential of the first sensing node SN1 to the reset voltage Vrst in response to the reset control signal SR. The reset control signal SR may be a signal provided through the reset control line SRL. However, the present disclosure is not limited thereto. In an embodiment, the reset control signal SR may be the j-th compensating scan signal SCj supplied through the j-th compensating scan line SCLj. In other words, the reset transistor ST1 may receive the j-th compensating scan signal SCj, which is supplied from the j-th compensating scan line SCLj, as the reset control signal SR. According to an embodiment of the present disclosure, the reset voltage Vrst may have a voltage level lower than a voltage level of the second driving voltage ELVSS at least during the activation period of the reset control signal SR. The reset voltage Vrst may be transmitted to the sensor FXdj through the reset voltage line VRL. The reset voltage Vrst may be a DC voltage maintained to be at a voltage level lower than a voltage level of the second driving voltage ELVSS.

The reset transistor ST1 may include a plurality of sub-reset transistors connected in series to each other. For example, the reset transistor ST1 may include two sub-reset transistors (hereinafter, referred to as “the first and second sub-reset transistors”). In this case, a third electrode of the first sub-reset transistor and a third electrode of the second sub-reset transistor are connected to the reset control line SRL. In addition, a second electrode of the first sub-reset transistor and a first electrode of the second sub-reset transistor may be electrically connected to each other. In addition, the reset voltage Vrst may be applied to the first electrode of the first sub-reset transistor, and the second electrode of the second sub-reset transistor may be electrically connected to the first sensing node SN1. However, the number of sub-reset transistors is not limited thereto, and may be variously modified.

The amplifying transistor ST2 includes a first electrode to receive a sensing driving voltage SLVD, a second electrode connected to the second sensing node SN2, and a third electrode connected to the first sensing node SN1. The amplifying transistor ST2 may be turned on based on the potential of the first sensing node SN1 to apply the sensing driving voltage SLVD to the second sensing node SN2. According to an embodiment of the present disclosure, the sensing driving voltage SLVD may be one of the first driving voltage ELVDD, and the first and second initializing voltages Vint and Vaint. When the sensing driving voltage SLVD is the first driving voltage ELVDD, the first electrode of the amplifying transistor ST2 may be electrically connected to the first driving voltage line VL1. When the sensing driving voltage SLVD is the first initializing voltage Vint, the first electrode of the amplifying transistor ST2 may be electrically connected to the first initializing voltage line VIL. When the sensing driving voltage SLVD is the second initializing voltage Vaint, the first electrode of the amplifying transistor ST2 may be electrically connected to the second initializing voltage line VAIL.

The output transistor ST3 includes a first electrode connected to the second sensing node SN2, a second electrode connected to the d-th readout line RLd, and a third electrode to receive the output control signal. The output transistor ST3 may transmit a sensing signal FSd to the d-th readout line RLd in response to the output control signal. The output control signal may be the j-th write scan signal SWj supplied through the j-th write scan line SWLj. In other words, the output transistor ST3 may receive the j-th write scan signal SWj, which is supplied from the j-th write scan line SWLj, as the output control signal.

When a user hand touches the display device DD (see FIG. 4), the light receiving element OPD generates photo charges corresponding to light reflected by a fingerprint ridge or a fingerprint valley between the fingerprint ridges. An amount of current flowing through the light receiving element OPD is varied depending on the generated photo charges. When the light receiving element OPD receives light reflected by the fingerprint ridge, a current flowing through the light receiving element OPD may be referred to as a first current. When the light receiving element OPD receives light reflected by the fingerprint valley, a current flowing through the light receiving element OPD may be referred to as a second current. An amount of light reflected by the fingerprint ridge are different from an amount of the light reflected by the fingerprint valley. Accordingly, this difference in the amount of light appears as a difference between the first current and the second current. When the first current flows through the light receiving element OPD, a potential of the first sensing node SN1 may be referred to as a first potential. When the second current flows through the light receiving element OPD, a potential of the first sensing node SN1 may be referred to as a second potential. According to an embodiment of the present disclosure, the first current may be greater than the second current. In this case, the first potential may be lower than the second potential.

The amplifying transistor ST2 may be a source follower amplifier to generate a source-drain current in proportion to the potential, which is input to the third electrode, of the first sensing node SN1.

During the fourth activation period AP4, the j-th write scan signal SWj having a low level is supplied to the output transistor ST3 through the j-th write scan line SWLj. When the output transistor ST3 is turned on in response to the j-th write scan signal SWj having the low level, the sensing signal FSd corresponding to a current flowing through the amplifying transistor ST2 may be output to the d-th readout line RLd.

Next, during the reset period, the reset transistor ST1 is turned on when the reset control signal SR having a high level is supplied through the reset control line SRL. The reset period may be defined as an activation period (that is, a high level period) of the reset control signal SR. In an embodiment, when the reset transistor ST1 is formed of the P-type transistor, the reset control signal SR having a low level may be supplied to the reset control line SRL during the reset period. During the reset period, the first sensing node SN1 may be reset with a potential corresponding to the reset voltage Vrst. According to an embodiment of the present disclosure, the reset voltage Vrst may have a voltage level lower than a voltage level of the second driving voltage ELVSS.

Next, when the reset period is terminated, the light receiving element OPD may generate photo charges corresponding to the received light, and the generated photo charges may be accumulated in the first sensing node SN1.

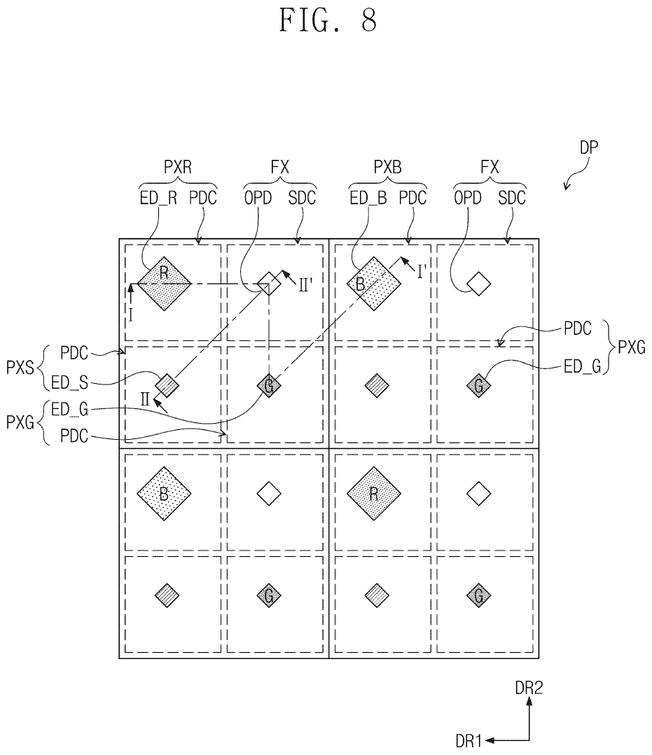

FIG. 8 is an enlarged plan view illustrating a partial region of a display panel DP according to an embodiment of the present disclosure.

Referring to FIG. 8, the display panel DP includes pixels PXR, PXG, and PXB, sub-pixels PXS, and sensors FX. The pixels PXR, PXG, and PXB include light emitting elements ED_R, ED_G, and ED_B and pixel driving circuits PDC, respectively. Each of the sub-pixels PXS includes a sub-light emitting element ED_S and the pixel driving circuit PDC. Each of the sensors FX includes a light receiving element OPD and a sensor driving circuit SDC.

The pixels PXR, PXG, and PXB, the sub-pixels PXS, and the sensors FX are alternately disposed in the first direction DR1 and are alternately disposed in the second direction DR2. The pixels PXR, PXG, and PXB include the first pixels PXR including light emitting elements (hereinafter referred to as a “first light emitting elements ED_R”) to emit light having a first color (for example., red (R)), the second pixels PXG including light emitting elements (hereinafter referred to as “second light emitting elements ED_G”) to emit light having a second color (for example, green (G)), and the third pixels PXB including light emitting elements (hereinafter referred to as “third light emitting elements ED_B”) to emit light having a third color (for example., blue (B)).

The sub-pixels PXS may include sub-light emitting elements ED_S which emit light having a color different from the first to third colors. For example, a wavelength of light emitted from a sub-light emitting element ED_S may range from 750 nm to 1,000 nm. Light emitted from the sub-light emitting element ED_S may be incident to the light receiving element OPD. As the wavelength of light emitted from the sub-light emitting element ED_S ranges from 750 nm to 1,000 nm, the light emitted from the sub-light emitting element ED_S may not be viewed by an external user.

Although FIG. 8 illustrates that the sub-light emitting elements ED_S included in the sub-pixels PXS, the present disclosure is not limited thereto. For example, the sub-light emitting element ED_S may be omitted. In this case, a light source disposed in the non-display region NDA of the display panel DP illustrated in FIG. 5 may serve as the sub-light emitting element ED_S. In other words, the wavelength of light emitted from the light source may range from 750 nm to 1,000 nm, and the light emitted from the light source may be incident to the light receiving element OPD.

As illustrated in FIG. 8, the first pixels PXR and the third pixels PXB may be alternately repeated in the first and second directions DR1 and DR2. The second pixels PXG may be arranged in the first direction DR1 and the second direction DR2.

Each sensor FX may be interposed between the first pixel PXR and the third pixel PXB adjacent to each other in the first direction DR1. Each sensor FX may be interposed between two second pixels PXG in the second direction DR2. Each of the sub-pixels PXS may be interposed between two second pixels PXG in the first direction DR1. Each sub-pixel PXS may be interposed between the first pixel PXR and the third pixel PXB adjacent to each other, in the second direction DR2. However, the arrangement of the pixels PXR, PXG, and PXB, the sub-pixels PXS, and the sensors FX are not limited thereto.

According to an embodiment of the present disclosure, the size of the first light emitting element ED_R may be greater than the size of the second light emitting element ED_G. In addition, the size of the third light emitting element ED_B may be greater than or equal to the size of the first light emitting element ED_R. The size of each of the first to third light emitting elements ED_R, ED_G, and ED_B is not limited thereto, and may be variously modified. For example, according to an embodiment of the present disclosure, the first to third light emitting elements ED_R, ED_G, and ED_B may have the same size.

In addition, although the first to third light emitting elements ED_R, ED_G, and ED_B having a rectangular shape are provided by way of example, the present disclosure is not limited thereto. For example, the first to third light emitting elements ED_R, ED_G, and ED_B may be implemented in a polygon shape, a circle shape, and an oval shape, respectively. According to an embodiment, the first to third light emitting elements ED_R, ED_G, and ED_B may be implemented in different shapes. In other words, the second light emitting element ED_G may have a circle shape, and the first and third light emitting elements ED_R and ED_B may have a rectangular shape.

The light receiving element OPD may have a size smaller than the sizes of the first and third light emitting elements ED_R and ED_B. According to an embodiment of the present disclosure, the size of the light receiving element OPD may be smaller than or equal to the size of the second light emitting element ED_G. However, the size of the light receiving element OPD is not limited thereto, and may be variously modified. Although the light receiving element OPD having the rectangular shape is provided by way of example, the present disclosure is not limited thereto. For example, the light receiving element OPD may be variously modified to have a polygon shape, a circle shape, or an oval shape.

Each of the sub-light emitting element ED_S and the first to third light emitting elements ED_R, ED_G, and ED_B is electrically connected to the relevant pixel driving circuit PDC. The pixel driving circuit PDC may include a plurality of transistors and a capacitor. The pixel driving circuits PDC connected to the sub-light emitting element ED_S and the first to third light emitting elements ED_R, ED_G, and ED_B, respectively, may have the same circuit configuration.

The light receiving element OPD is electrically connected with the relevant sensor driving circuit SDC. The sensor driving circuit SDC may include a plurality of transistors. According to an embodiment of the present disclosure, the sensor driving circuit SDC and the pixel driving circuit PDC may be formed simultaneously through the same process.

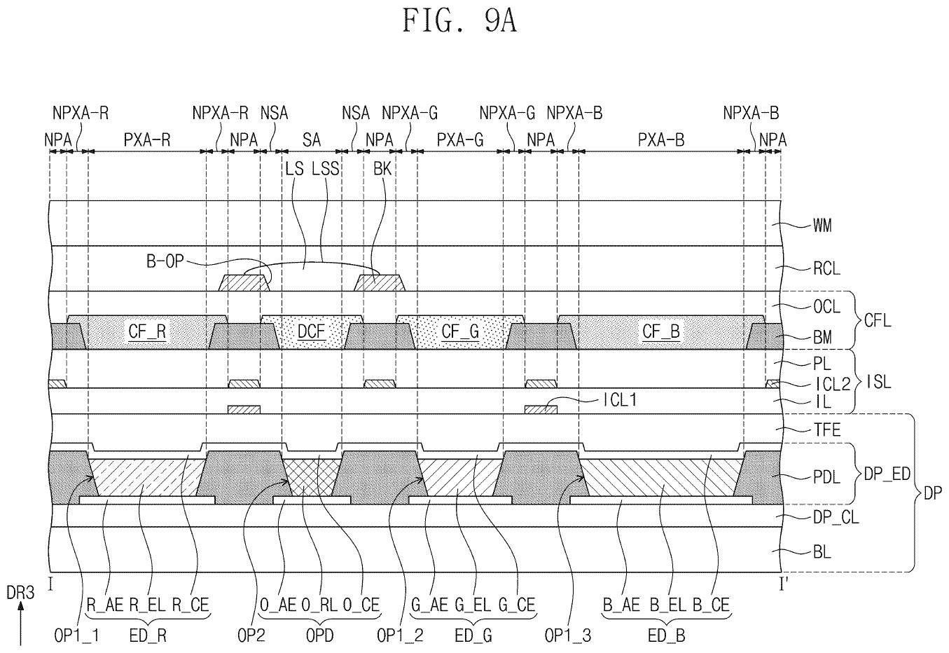

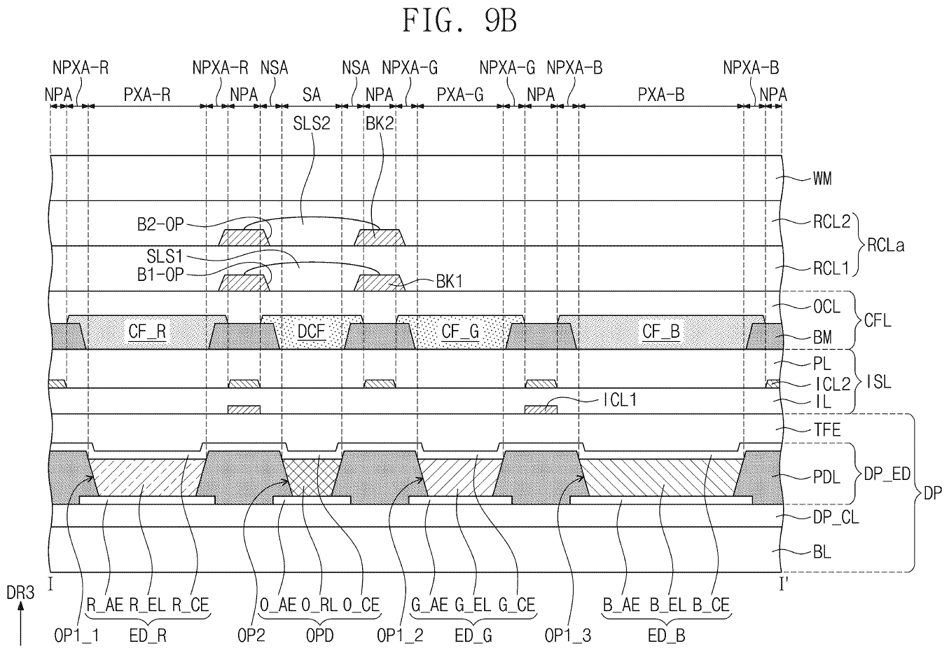

FIG. 9A is a cross-sectional view of a display device taken along line I-I′ illustrated in FIG. 8 according to an embodiment of the present disclosure.

Referring to FIG. 9A, a first electrode layer is disposed on the circuit layer DP_CL. A pixel defining layer PDL is formed on the first electrode layer. The first electrode layer may include red, green, and blue anode electrodes R_AE, G_AE, and B_AE. First to third light emitting openings OP1_1, OP1_2, and OP1_3 in the pixel defining layer PDL expose at least a portion of the red, green, and blue anode electrodes R_AE, G_AE, and B_AE, respectively. According to an embodiment of the present disclosure, the pixel defining layer PDL may further include a black material. The pixel defining layer PDL may further include a black organic dye/pigment such as carbon black or aniline black. The pixel defining layer PDL may be formed by mixing a blue organic material and a black organic material. The pixel defining layer PDL may further include a liquid-repellent organic material.

The display panel DP may include first to third light emitting regions PXA-R, PXA-G, and PXA-B, and first to third non-light emitting regions NPXA-R, NPXA-G, and NPXA-B adjacent to the first to third light emitting regions PXA-R, PXA-G, and PXA-B. Each of the non-light emitting regions NPXA-R, NPXA-G, and NPXA-B may surround the relevant light emitting regions PXA-R, PXA-G, and PXA-B. According to an embodiment, the first light emitting region PXA-R is defined to correspond to a partial region of the red anode electrode R_AE exposed through the first opening OP1_1. The second light emitting region PXA-G is defined to correspond to a partial region of a green anode electrode G_AE exposed through the second opening OP1_2. The third light emitting region PXA-B is defined to correspond to a partial region of a blue anode electrode B_AE exposed through the third opening OP1_3. Non-pixel regions NPA may be defined between two adjacent non-light emitting regions among the first to third non-light emitting regions NPXA-R, NPXA-G, and NPXA-B.

An emission layer may be disposed on the first electrode layer. The emission layer may include the red, green, and blue emission layers R_EL, G_EL, and B_EL. The red, green, and blue emission layers R_EL, G_EL, and B_EL may be disposed in regions corresponding to first to third light emitting openings OP1_1, OP1_2, and OP1_3, respectively. The red, green, and blue emission layers R_EL, G_EL, and B_EL may be formed separately from each other. The red, green, and blue emission layers R_EL, G_EL, and B_EL may include an organic material and/or an inorganic material. The red, green, and blue emission layers R_EL, G_EL, and B_EL may generate specific color light. For example, the red emission layer R_EL may generate red light, the green emission layer G_EL may generate green light, and the blue emission layer B_EL may generate blue light.

Although the red, green, and blue emission layers R_EL, G_EL, and B_EL, which are patterned, are provided by way of example according to an embodiment, one emission layer may be commonly disposed in the first to third light emitting regions PXA-R, PXA-G, and PXA-B. In this case, the emission layer may generate white light or blue light. In addition, the emission layer may have a multi-layer structure referred to as a tandem.

Each of the red, green, and blue emission layers R_EL, G_EL, and B_EL may include a low-molecular organic material or a high-molecular organic material serving as a light emitting material. Each of the red, green, and blue emission layers R_EL, G_EL, and B_EL may include a quantum dot material as a light emitting material. The core of the quantum dot may include a material selected from the group II-IV compound, the group III-V compound, the group IV-VI compound, the group IV element, the group IV compound, and the combination thereof.

A second electrode layer is disposed on the red, green, and blue emission layers R_EL, G_EL, and B_EL. The second electrode layer may include the red, green, and blue cathode electrodes R_CE, G_CE, and B_CE. The red, green, and blue cathode electrodes R_CE, G_CE, and B_CE may be electrically connected to each other. According to an embodiment of the present disclosure, the red, green, and blue cathode electrodes R_CE, G_CE, and B_CE may have an integral form with each other. In this case, the red, green, and blue cathode electrodes R_CE, G_CE, and B_CE may be disposed in common in the first to third light emitting regions PXA-R, PXA-G, and PXA-B, the first to third non-light emitting regions NPXA-R, NPXA-G, and NPXA-B, and the non-pixel region NPA.

The display layer DP_ED may further include the light receiving element OPD. The light receiving element OPD may be a photodiode. The pixel defining layer PDL may further include a light receiving opening OP2 which is provided to correspond to the light receiving element OPD.

The light receiving element OPD may include a sensing anode electrode O_AE, a photoelectric conversion layer O_RL, and a sensing cathode electrode O_CE. The sensing anode electrode O_AE may be disposed on the same layer as the layer for the first electrode layer. In other words, the sensing anode electrode O_AE may be disposed on the circuit layer DP_CL, and may be simultaneously formed with the red, green, and blue anode electrodes R_AE, G_AE, and B_AE through the same process. The sensing anode electrode O_AE may be referred to as a first sensing electrode, and the sensing cathode electrode O_CE is referred to as a second sensing electrode.

The light receiving opening OP2 of the pixel defining layer PDL exposes at least a portion of the sensing anode electrode O_AE. The photoelectric conversion layer O_RL is disposed on the sensing anode electrode O_AE exposed by the light receiving opening OP2. The photoelectric conversion layer O_RL may include an organic photo sensing material. The sensing cathode electrode O_CE may be disposed on the photoelectric conversion layer O_RL. The sensing cathode electrode O_CE may be simultaneously formed with the red, green, and blue cathode electrodes R_CE, G_CE, and B_CE through the same process. According to an embodiment of the present disclosure, the sensing cathode electrode O_CE may have an integral form with the red, green, and blue cathode electrodes R_CE, G_CE, and B_CE, thereby forming a common cathode electrode.

The encapsulating layer TFE is disposed above the display layer DP_ED. The encapsulating layer TFE includes at least an inorganic layer or an organic layer. According to an embodiment of the present disclosure, the encapsulating layer TFE may include two inorganic layers and an organic layer interposed between the two inorganic layers. According to an embodiment of the present disclosure, the encapsulating layer TFE may include a plurality of inorganic layers and a plurality of organic layers alternately stacked.

The inorganic layer protects the first to third light emitting elements ED_R, ED_G, and ED_B, and the light receiving element OPD from moisture/oxygen, and the organic layer protects the first to third light emitting elements ED_R, ED_G, and ED_B and the light receiving element OPD from foreign substances such as dust particles. The inorganic layer may include a silicon nitride layer, a silicon oxynitride layer, a silicon oxide layer, a titanium oxide layer, an aluminum oxide layer, but the present disclosure is not particularly limited thereto. The organic layer may include an acrylic-based organic layer, but the present disclosure is not particularly limited thereto.

The display device DD (see FIG. 4) includes the input sensing layer ISL disposed on the display panel DP, a color filter layer CFL disposed on the input sensing layer ISL, and a light control layer RCL disposed on the color filter layer CFL.

The input sensing layer ISL may be directly disposed on the encapsulating layer TFE. The input sensing layer ISL includes a first conductive layer ICL1, an insulating layer IL, a second conductive layer ICL2, and a protective layer PL. The first conductive layer ICL1 may be disposed on the encapsulating layer TFE. Although FIG. 9A illustrates a structure in which the first conductive layer ICL1 is directly disposed on the encapsulating layer TFE, the present disclosure is not limited thereto.

The input sensing layer ISL may further include a base insulating layer interposed between the first conductive layer ICL1 and the encapsulating layers TFE. In this case, the encapsulating layer TFE may be covered by the base insulating layer, and the first conductive layer ICL1 may be disposed on the base insulating layer. According to an embodiment of the present disclosure, the base insulating layer may include an inorganic insulating material. The insulating layer IL may cover the first conductive layer ICL1. The second conductive layer ICL2 is disposed on the insulating layer IL. Although the structure in which the input sensing layer ISL includes the first and second conductive layers ICL1 and ICL2 is illustrated, the present disclosure is not limited thereto. For example, the input sensing layer ISL may include only one of the first and second conductive layers ICL1 and ICL2.

The protective layer PL may be disposed on the second conductive layer ICL2. The protective layer PL may include an organic insulating material. The protective layer PL may serve to protect the first and second conductive layers ICL1 and ICL2 from moisture/oxygen and protect the first and second conductive layers ICL1 and ICL2 from foreign substances.

The color filter layer CFL may be disposed on the input sensing layer ISL. The color filter layer CFL may be directly disposed on the protective layer PL. The color filter layer CFL may include the first color filter CF_R, the second color filter CF_G, and the third color filter CF_B. The first color filter CF_R has a first color, the second color filter CF_G has a second color, and the third color filter CF_B has a third color. According to an embodiment of the present disclosure, the first color may be red, the second color may be green, and the third color may be blue.

The color filter layer CFL may further include a dummy color filter DCF. According to an embodiment of the present disclosure, when a region for disposing the photoelectric conversion layer O_RL is defined as a sensing region SA and a peripheral region of the sensing region SA is defined as a non-sensing region NSA, the dummy color filter DCF may be disposed to correspond to the sensing region SA. The dummy color filter DCF may be overlapped with the sensing region SA and the non-sensing region NSA. According to an embodiment of the present disclosure, the dummy color filter DCF may have the same color as a color of one of the first to third color filters CF_R, CF_G, and CF_B. According to an embodiment of the present disclosure, the dummy color filter DCF may have a green color, which is a color the same as a color of the second color filter CF_G.

The color filter layer CFL may further include a black matrix BM. The black matrix BM may be disposed to correspond to the non-pixel region NPA. The black matrix BM may be disposed to be overlapped with the first and second conductive layers ICL1 and ICL2 in the non-pixel region NPA. According to an embodiment of the present disclosure, the black matrix BM may be overlapped with the non-pixel region NPA and the first to third non-light emitting regions NPXA-G, NPXA-B, and NPXA-R. The black matrix BM may be in a non-overlap state with the first to third light emitting regions PXA-R, PXA-G, and PXA-B.

The color filter layer CFL may further include an overcoating layer OCL. The overcoating layer OCL may include an organic insulating material. The overcoating layer OCL may have a thickness sufficient to remove a step difference between the first to third color filters CF_R, CF_G and CF_B. The overcoating layer OCL may include any material having a specific thickness to planarize a top surface of the color filter layer CFL without being particularly limited. For example, the overcoating layer OCL may include an acrylate-based organic material.

An optical control layer RCL may be disposed on the color filter layer CFL. The optical control layer RCL may include a bank BK and a lens LS disposed in a bank opening B-OP defined in the bank BK. The bank BK may be directly disposed on the color filter layer CFL. The bank BK may be overlapped with the black matrix BM. The bank BK may include a polyimide-based resin. However, the present disclosure is not limited thereto. For example, the bank BK may include a light absorbing material. The light absorbing material may include a black pigment or a black dye. Carbon black may be used as the black pigment or black dye, but an embodiment is not limited thereto.

The lens LS may be disposed inside the bank opening B-OP to be overlapped with the light receiving element OPD. The lens LS may be a resin pattern formed by mixing optical particles with a base resin.

The lens LS may fill the bank opening B-OP of the bank BK and may protrude from an upper end of the bank BK in the third direction DR3. The lens LS may cover the bank opening B-OP of the bank BK, but may not cover a top surface of the bank BK. The lens LS may have a shape protruding from the bank BK such that the thickness of the lens LS is increased from a meeting point between the lens LS and an upper portion of the bank opening B-OP to the center of the lens LS when viewed in a plan view. The top surface of the lens LS is defined as a lens surface LSS. The top surface of the lens LS may be a curved surface.

The window WM may be disposed on the optical control layer RCL.

FIG. 9B is a cross-sectional view of a display device taken along line I-I′ illustrated in FIG. 8 according to an embodiment of the present disclosure. The repetition of the above description will be omitted to avoid redundancy.

Referring to FIG. 9B, according to the present disclosure, an optical control layer RCLa may include a first optical control layer RCL1 and a second optical control layer RCL2 sequentially stacked. The first optical control layer RCL1 may include a first bank BK1 and a first sub-lens SLS1 disposed in a first bank opening B1-OP defined in the first bank BK1, and the second optical control layer RCL2 may include a second bank BK2 and a second sub-lens SLS2 disposed in a second bank opening B2-OP defined in the second bank BK2. The first sub-lens SLS1 and the second sub-lens SLS2 may be overlapped with each other when viewed in a plan view.

The first sub-lens SLS1 and the second sub-lens SLS2 may correspond to the lens LS illustrated in FIG. 9A. In other words, the first sub-lens SLS1 and the second sub-lens SLS2 illustrated in FIG. 9B may be embodiments for changing the refractive index of the lens LS illustrated in FIG. 9A. A focal length made by the first sub-lens SLS1 and the second sub-lens SLS2 overlapped with each other when viewed in a plan view may be longer than a focal length of the lens LS illustrated in FIG. 9A.

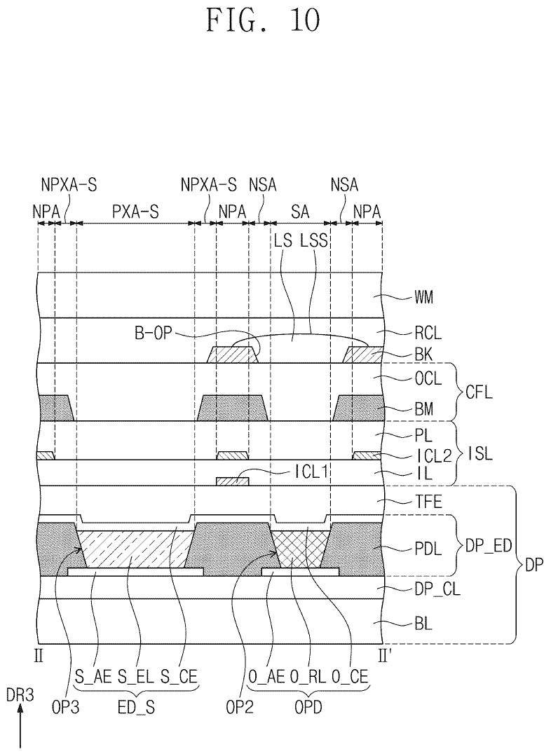

FIG. 10 is a cross-sectional view of a display device taken along line II-II′ illustrated in FIG. 8 according to an embodiment of the present disclosure.

Referring to FIG. 10, the sub-light emitting element ED_S may be disposed adjacent to the light receiving element OPD. The sub-light emitting element ED_S may include a sub-anode electrode S_AE, a sub-emission layer S_EL, and a sub-cathode electrode S_CE, which are sequentially stacked. The sub-emission layer S_EL may be disposed in a sub-light emitting opening OP3 defined by the pixel defining layer PDL. The display panel DP may include a first sub-light emitting area PXA-S and a first non-sub-light emitting area NPXA-S adjacent to the first sub-light emitting area PXA-S. The first sub-light emitting area PXA-S is defined as a portion of the area corresponding to the sub-anode electrode S_AE that is exposed through the sub-light emitting opening OP3. The sub-emission layer S_EL may generate specific light. For example, a wavelength of light generated by the sub-emission layer S_EL may range from 750 nm to 1,000 nm.

The sub-emission layer S_EL may include a quantum dot material as a light emitting material. The core of the quantum dot may be selected from a group II-VI compound, a group III-V compound, a group IV-VI compound, a group IV element, a group IV compound, and a combination thereof.

According to an embodiment of the present disclosure, the light receiving element OPD may be a quantum dot photodiode including a quantum dot material in a photoelectric conversion layer O_RL. In other words, the photoelectric conversion layer O_RL may include a quantum dot photo sensing material. Accordingly, when light having a wavelength ranging from 750 nm to 1,000 nm is incident to the light receiving element OPD, the light receiving element OPD may generate photo charges and sense external gestures.

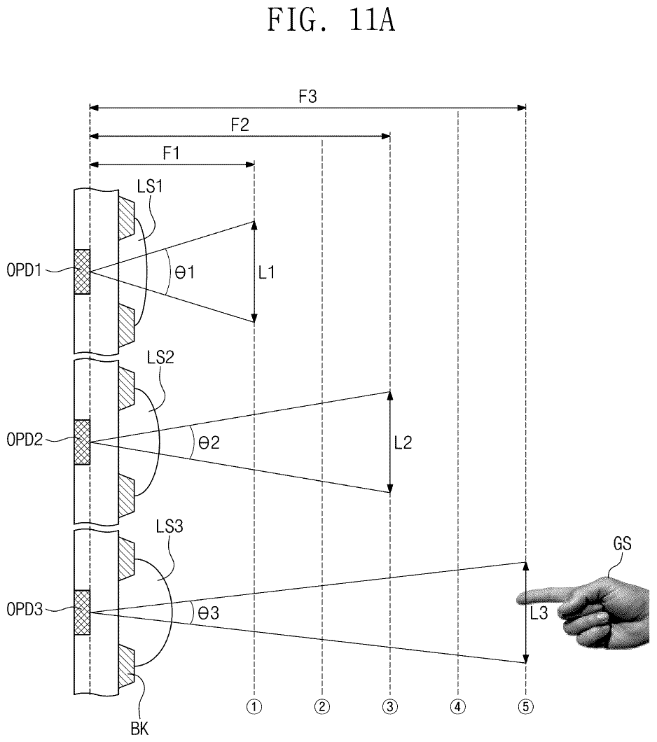

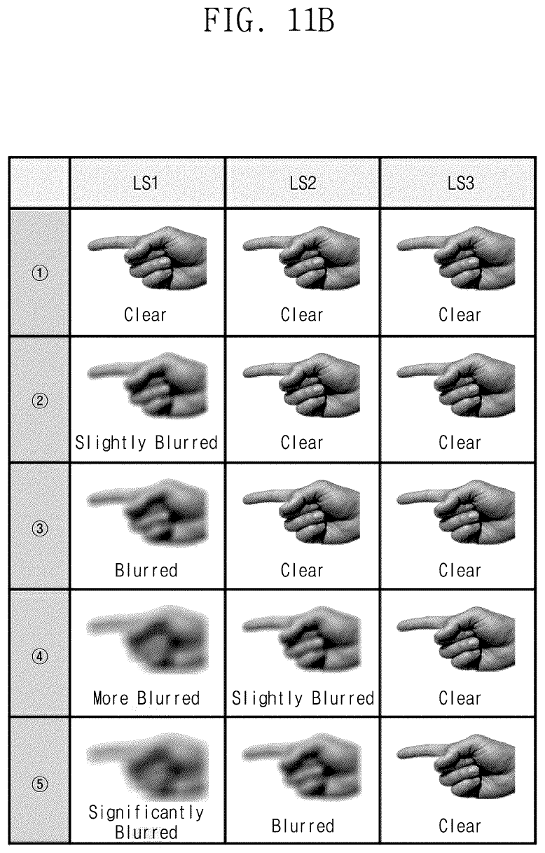

FIG. 11A is a view schematically illustrating a plurality of light receiving elements OPD1, OPD2, and OPD3 and lenses LS1, LS2, and LS3 according to the present disclosure. FIG. 11B is a view to describe FIG. 11A.

Referring to FIG. 11A, the plurality of light receiving elements OPD1, OPD2, and OPD3, and the lenses LS1, LS2, and LS3 corresponding to the plurality of light receiving elements OPD1, OPD2, and OPD3, respectively, may be disposed. The plurality of light receiving elements OPD1, OPD2, and OPD3 and the lenses LS1, LS2, and LS3 may correspond to embodiments of the light receiving element OPD and the lens LS illustrated in FIG. 9A.

For example, the plurality of light receiving elements OPD1, OPD2, and OPD3 include the first to third light receiving elements OPD1, OPD2, and OPD3, and the lenses LS1, LS2, and LS3 include the first to third lenses LS1, LS2, and LS3. The first lens LS1 may be disposed on the first light receiving element OPD1, the second lens LS2 may be disposed on the second light receiving element OPD2, and the third lens LS3 may be disposed on the third light receiving element OPD3.

The first lens LS1 may have a first focal length F1, the second lens LS2 may have a second focal length F2, and the third lens LS3 may have a third focal length F3. Accordingly, the first lens LS1, the second lens LS2, and the third lens LS3 may have different field of views (FOV). For example, the FOV of the first lens LS1 may be defined as a first angle θ1, the FOV of the second lens LS2 may be defined as a second angle θ2, and the FOV of the third lens LS3 may be defined as a third angle θ3.

The first to third angles θ1, θ2, and θ3 may be determined within a range in which light incident to the first to third light receiving elements OPD1, OPD2, and OPD3 are not superimposed with each other. For example, the FOV for the first focal length F1 may be defined as the first angle θ1 based on a first distance L1 corresponding to a visible range of the first light receiving element OPD1. The FOV for the second focal length F2 may be defined as the second angle θ2 based on a second distance L2 corresponding to a visible range of the second light receiving element OPD2. The FOV for the third focal length F3 may be defined as a third angle θ3 based on a third distance L3 corresponding to a visible range of the third light receiving element OPD3. As illustrated in the drawing, the third focal length F3 is greater than the second focal length F2, and the second focal length F2 is greater than the first focal length F1. In addition, the first angle θ1 is greater than the second angle θ2, and the second angle θ2 is greater than the third angle θ3.

The first to third focal lengths F1, F2, and F3 may be varied depending on a relevant one of refractive indexes of the first to third lenses LS1, LS2, and LS3 or a relevant one of top surfaces of the first to third lenses LS1, LS2, and LS3. For example, the refractive index of the first lens LS1 having the shortest focal length may be greater than the refractive index of each of the second lens LS2 and the third lens LS3. In an embodiment, the curvature of the top surface of the third lens LS3 having the longest focal length may be greater than the curvature of each of the top surfaces of the second lens LS2 and the first lens LS1.

Referring to FIGS. 11A and 11B together, when a gesture GS, which is made by a user finger, is disposed from position \textcircled{1} to position \textcircled{5}, the sharpness of the gesture GS may be determined through the first to third light receiving elements OPD1, OPD2, and OPD3.

Specifically, for an image obtained through the first lens LS1, it may be recognized that the gesture GS has a clear sharpness at position \textcircled{1}, but has a significant blurred sharpness at position \textcircled{5}. For an image obtained through the second lens LS2, it may be recognized that the gesture GS has a clear sharpness at positions \textcircled{1} to \textcircled{3}, but has a significant blurred sharpness at position \textcircled{5}. In addition, for the image obtained through the third lens LS3, it may be recognized that the gesture GS has a clear sharpness at position \textcircled{1} to \textcircled{5}.

In other words, according to the present disclosure, the display device DD (see FIG. 4) may collect data on sharpness of the gesture GS sensed from the outside of the display device DD, as the lens LS1, LS2, and LS3 having mutually different focal lengths are disposed on the light receiving elements OPD1, OPD2, and OPD3. Accordingly, the display device DD may determine the distance from the display device DD to the gesture GS, and may enhance the recognition accuracy of the gesture GS. In other words, the display device DD may be provided with the improved sensing function.

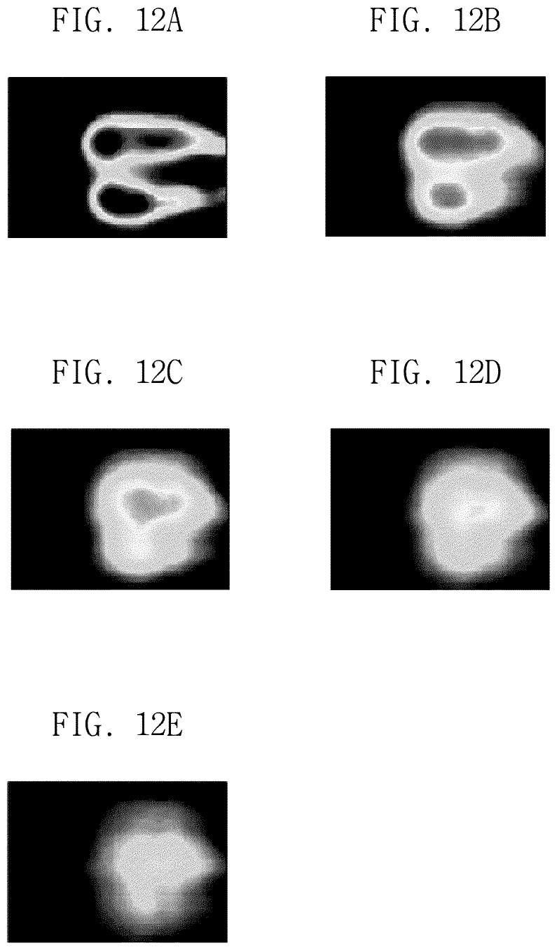

FIGS. 12A to 12E are views illustrating the sharpness of a gesture based on a spacing between gestures. For example, FIGS. 12A to 12E are views illustrating the sharpness of the gesture varied depending on a spacing between gestures within the third distance L3 when the gesture is positioned at the position \textcircled{5} as illustrated in FIG. 11A. FIG. 12A is an image which is recognized by the light receiving element when a separation distance is 10 mm. FIG. 12B is an image which is recognized by the light receiving element when the separation distance is 20 mm.

FIG. 12C is an image which is recognized by the light receiving element when the separation distance is 30 mm. FIG. 12D is an image which is recognized by the light receiving element when the separation distance is 40 mm. FIG. 12E is an image which is recognized by the light receiving element when the separation distance is 50 mm.

Hereinafter, Table 1 shows conversion distances depending on the separation distance and the FOVs.

TABLE 1

| | | Separation distance (mm) | | | | |
|---|---|---|---|---|---|---|
| | Angle (°) | 10 | 20 | 30 | 40 | 50 |
| Conversion | 1 | 581 | 1163 | 1744 | 2325 | 2907 |
| distance | 2 | 291 | 581 | 872 | 1163 | 1453 |
| (mm) | 3 | 194 | 387 | 581 | 775 | 969 |
| | 4 | 145 | 291 | 436 | 581 | 726 |
| | 5 | 116 | 232 | 349 | 465 | 581 |
| | 6 | 97 | 194 | 290 | 387 | 484 |
| | 7 | 83 | 166 | 249 | 332 | 415 |
| | 8 | 73 | 145 | 218 | 290 | 363 |
| | 9 | 64 | 129 | 193 | 258 | 322 |
| | 10 | 58 | 116 | 174 | 232 | 290 |
| | 11 | 53 | 105 | 158 | 211 | 263 |
| | 12 | 48 | 97 | 145 | 193 | 241 |

In Table 1, the FOV is an angle based on the focal length of each lens, and the separation distance corresponds to the spacing (or an image corresponding to the spacing) between gestures as described above. In addition, the described values are values obtained by quantifying the distance between the light receiving elements OPD1, OPD2, and OPD3 (see FIG. 11A) and the gesture GS (see FIG. 11A). For example, the FOV may be 2°, and the distance between the light receiving elements OPD1, OPD2, and OPD3 (see FIG. 11A) and the gesture GS (see FIG. 11A) may be 291 mm, which refers to that an image (that is, an image illustrated in FIG. 12A) having the spacing of 10 mm may be captured.

According to the present disclosure, the sharpness extent of the images illustrated in FIGS. 12A and 12B needs to be ensured. Accordingly, the lenses having the FOVs corresponding to the separation distances of 10 mm and 20 mm need to be arranged. For example, it may be recognized that the FOVs of the lenses LS1, LS2, and LS3 (see FIG. 11A) according to the present disclosure are 2°, 3° and 6° to capture images illustrated in FIG. 12A, when the distances between the light receiving elements OPD1, OPD2, and OPD3 (see FIG. 11A) and the gesture GS (see FIG. 11A) are 100 mm, 200 mm, and 300 mm, respectively. In addition, it may be recognized that the FOVs of the lenses LS1, LS2, and LS3 (see FIG. 11A) according to the present disclosure are 4°, 6° and 12° to capture images illustrated in FIG. 12B, when the distances between the light receiving elements OPD1, OPD2, and OPD3 (see FIG. 11A) and the gesture GS (see FIG. 11A) are 100 mm, 200 mm, and 300 mm, respectively.

In other words, when the FOVs of the lenses LS1, LS2, and LS3 (see FIG. 11A) according to the present disclosure are 2°, 3° and 6°, the recognition accuracy for the image of the gesture GS (see FIG. 11A) illustrated in FIG. 12A may be enhanced. In addition, when the FOVs of the lenses LS1, LS2, and LS3 (see FIG. 11A) according to the present disclosure are 4°, 6° and 12°, the recognition accuracy for the image of the gesture GS (see FIG. 11A) illustrated in FIG. 12B may be enhanced.

According to the present disclosure, the lenses having various focal lengths are disposed on the light receiving elements and data on the sharpness of gestures sensed at the outside of the display device is collected, thereby determining the distance from the display device to the gesture and enhancing the recognition accuracy of the gesture. In other words, the display device may be provided with the improved sensing function.

Although an embodiment of the present disclosure has been described for illustrative purposes, those skilled in the art will appreciate that various modifications, and substitutions are possible, without departing from the scope and spirit of the present disclosure as disclosed in the accompanying claims.

Accordingly, the technical scope of the present disclosure is not limited to the detailed description of this specification, but should be defined by the claims.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A display device comprising:
a base layer;
a circuit layer disposed on the base layer;
an element layer disposed on the circuit layer and including a plurality of light emitting elements and a plurality of light receiving elements adjacent to each other; and
an optical control layer including a plurality of lenses overlapping the plurality of light receiving elements in a plan view,
wherein the plurality of lenses include:
a first lens having a first focal length; and
a second lens having a second focal length different from the first focal length.

2. The display device of claim 1, wherein the plurality of light emitting elements include:
a first light emitting element to emit first light having a first wavelength range; and
a second light emitting element to emit second light having a second wavelength range different from the first wavelength range, and
wherein a light receiving element of the plurality of light receiving elements receives the first light.

3. The display device of claim 2, wherein the first wavelength range is equal to or greater than 750 nm and equal to or less than 1,000 nm.

4. The display device of claim 2, wherein the first light emitting element, the second light emitting element, and the plurality of light receiving elements are disposed on a same layer.

5. The display device of claim 1, wherein the base layer includes:
a display region for disposing the plurality of light emitting elements and a non-display region surrounding the display region, and
wherein the display device further includes:
a light source disposed in the non-display region.

6. The display device of claim 5, wherein the light source emits first light having a first wavelength range,
wherein the plurality of light emitting elements emit second light having a second wavelength range different from the first wavelength range, and
wherein the first wavelength range is equal to or greater than 750 nm and equal to or less than 1,000 nm.

7. The display device of claim 1, wherein the plurality of light emitting elements include:
an anode electrode electrically connected to the circuit layer, an emission layer disposed on the anode electrode, and a cathode electrode disposed on the emission layer, and
wherein a light receiving element of the plurality of light receiving elements includes:
a first sensing electrode electrically connected to the circuit layer, a photoelectric conversion layer disposed on the first sensing electrode, and a second sensing electrode disposed on the photoelectric conversion layer.

8. The display device of claim 7, wherein the light receiving element is a quantum dot photodiode.

9. The display device of claim 1, wherein the optical control layer includes:
a first optical control layer and a second optical control layer sequentially stacked, and
wherein the first lens includes:
a first sub-lens disposed in the first optical control layer, and
a second sub-lens disposed in the second optical control layer.

10. The display device of claim 9, wherein the first sub-lens overlaps the second sub-lens in a plan view.

11. The display device of claim 1, wherein the plurality of lenses further include:
a third lens including a third focal length different from the first focal length and the second focal length.

12. The display device of claim 1, wherein the optical control layer further includes:
a bank in which a plurality of openings overlapping the light receiving elements are defined, and
wherein the plurality of lenses are disposed in the plurality of openings, respectively.

13. The display device of claim 12, wherein each of the first lens and the second lens protrude upward from an upper portion of the bank.

14. The display device of claim 12, wherein each of the first lens and the second lens has a top surface including a curved surface, and
wherein a curvature of the curved surface of the first lens is different from a curvature of the curved surface of the second lens.

15. The display device of claim 1, further comprising:
a color filter layer interposed between the element layer and the optical control layer.

16. A display device comprising
a base layer;
a circuit layer disposed on the base layer;
an element layer disposed on the circuit layer and including a plurality of light emitting elements and a plurality of light receiving elements disposed on a same layer; and
wherein the plurality of light emitting elements include:
a first light emitting element to emit first light having a first wavelength range; and
a second light emitting element to emit second light having a second wavelength range different from the first wavelength range,
wherein a light receiving element of the plurality of light receiving elements receives the first light, and
wherein the first wavelength range is equal to or greater than 750 nm and equal to or less than 1,000 nm.

17. The display device of claim 16, wherein the first light emitting element, the second light emitting element, and the plurality of light receiving elements are disposed on the same layer.

18. The display device of claim 16, further comprising:
an optical control layer including a plurality of lenses overlapping the plurality of light receiving elements in a plan view,
wherein the plurality of lenses include:
a first lens having a first focal length; and
a second lens having a second focal length different from the first focal length.

19. The display device of claim 18, wherein the optical control layer includes:
a first optical control layer and a second optical control layer sequentially stacked, and
wherein the first lens includes:
a first sub-lens disposed in the first optical control layer; and
a second sub-lens disposed in the second optical control layer.

20. An electronic device comprising:
a display device configured to display an image; and
one or more processors configured to provide image data to the display device,
wherein the display device includes:
a base layer;
a circuit layer disposed on the base layer;
an element layer disposed on the circuit layer and including a plurality of light emitting elements and a plurality of light receiving elements adjacent to each other;
an optical control layer including a plurality of lenses overlapping the plurality of light receiving elements in a plan view; and
a window disposed on the optical control layer, and
wherein the plurality of lenses include:
a first lens having a first focal length; and
a second lens having a second focal length different from the first focal length.
